(19) United States
(12) Patent Application Publication
(10) Pub. No.: US 2025/0138424 A1
(43) Pub. Date: May 1, 2025

(54) PHOTOREACTIVE POLYMER COMPOUND, PHOTORESIST COMPOSITION INCLUDING THE SAME, AND METHOD OF FORMING PATTERN BY USING THE PHOTORESIST COMPOSITION

(71) Applicant: Samsung Electronics Co., Ltd., Suwon-si (KR)

(72) Inventors: Dmitry ANDROSOV, Suwon-si (KR); Cheol KANG, Suwon-si (KR); Hana KIM, Suwon-si (KR); Sungan DO, Hwaseong-si (KR); Yonghoon MOON, Hwaseong-si (KR); Hoyoon PARK, Suwon-si (KR); Jaejun LEE, Suwon-si (KR)

(73) Assignee: Samsung Electronics Co., Ltd., Suwon-si (KR)

(21) Appl. No.: 18/613,917

(22) Filed: Mar. 22, 2024

(30) Foreign Application Priority Data
Oct. 31, 2023 (KR) 10-2023-0148437

(51) Int. Cl. G03F 7/039

(52) U.S. Cl. CPC G03F 7/039

(57) ABSTRACT

Provided are a photoreactive polymer compound including a first repeating unit represented by Formula 1, a photoresist composition including the same, and a method of forming a pattern by using the photoresist composition:

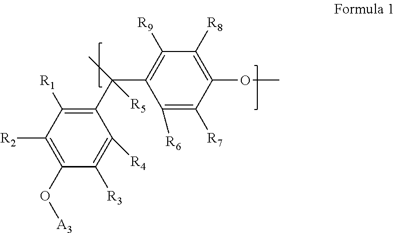

wherein a description of Formula 1 is provided in the present specification.

### CROSS-REFERENCE TO RELATED APPLICATION

This application is based on and claims priority under 35 U.S.C. § 119 to Korean Patent Application No. 10-2023-0148437, filed on Oct. 31, 2023, in the Korean Intellectual Property Office, the disclosure of which is incorporated by reference herein in its entirety.

### BACKGROUND

### 1. Field

The disclosure relates to a photoreactive polymer compound, a photoresist composition including the same, and a method of forming a pattern by using the photoresist composition.

### 2. Description of the Related Art

In semiconductor manufacturing, photoresists (for which physical properties change in response to light) are used to form fine patterns. Among these photoresists, chemically amplified photoresists have been widely used. A chemically amplified photoresist enables patterning by changing the solubility of a base resin in a developing solution by reaction of an acid, which is formed by a reaction between light and a photoacid generator, with the base resin again.

However, in the case of a chemically amplified photoresist, problems such as a decrease in pattern uniformity as the formed acid diffuses even to an unexposed area or an increase in surface roughness may be caused.

Recently, attempts have been made to develop materials of which physical properties change in response to light exposure, to overcome the limitations of chemically amplified resists.

### SUMMARY

Provided are a resist composition and a method of forming a pattern by using the resist composition, wherein physical properties of the resist composition change even in response to light exposure at low doses and the resist composition is capable of providing a pattern with improved resolution.

Additional aspects will be set forth in part in the description which follows and, in part, will be apparent from the description, or may be learned by practice of the presented embodiments of the disclosure.

According to an aspect of the disclosure, a photoreactive polymer compound includes a first repeating unit represented by Formula 1:

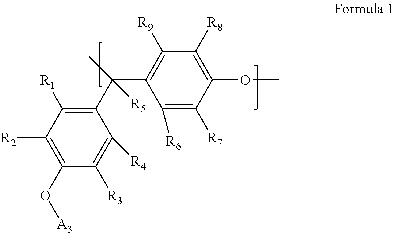

wherein, in Formula 1,
A₃ and R₁ to R₉ may each independently be hydrogen, deuterium, a halogen, a cyano group, a nitro group, a hydroxy group, a C₁-C₃₀ monovalent hydrocarbon group that optionally includes a heteroatom, or —N(Q₁)(Q₂), and
Q₁ and Q₂ may each independently be hydrogen, deuterium, or a linear, branched, or cyclic C₁-C₂₀ monovalent hydrocarbon group that optionally includes a heteroatom, and
the photoreactive polymer compound may include at least one photosensitive group.

According to another aspect of the disclosure, a photoresist composition includes the photoreactive polymer compound.

According to another aspect of the disclosure, a method of forming a pattern includes forming a photoresist film by applying the photoresist composition, exposing at least a portion of the photoresist film to high-energy rays, and developing the exposed photoresist film using a developing solution.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flowchart illustrating a pattern formation method according to an embodiment;

FIG. 2 is a side cross-sectional view illustrating a pattern formation method according to an embodiment; and

FIGS. 3 to 8 are each a diagram showing 1H-NMR spectra of photoreactive polymer compounds according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figure, to explain aspects. As used herein, the term “and/or” includes any and all combinations of one or more of the associated listed items. Expressions such as “at least one of,” when preceding a list of elements, modify the entire list of elements and do not modify the individual elements of the list.

As embodiments allow for various changes and numerous embodiments, exemplary embodiments will be illustrated in the drawings and described in detail in the written description. However, this is not intended to limit embodiments to particular modes of practice, and it is to be appreciated that all changes, equivalents, and substitutes that do not depart from the spirit and technical scope of the disclosure are encompassed in embodiments. In the description of embodiments certain detailed explanations of the related art are omitted when it is deemed that they may unnecessarily obscure the essence of the disclosure.

Terms such as “first”, “second”, “third”, and the like may be used to describe various components, but are used only for the purpose of distinguishing one component from other components, and the order, type, and the like of the components are not limited.

It will be understood that when a component, such as a layer, a film, a region, or a plate, is referred to as being “on” or “above” another component in the specification, the component can directly contact to be above, below, right, or left of the other component as well as being above, below, left, or right of the other component in a non-contact manner. For example, it will be understood that such spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly.

An expression used in the singular encompasses the expression of the plural, unless it has a clearly different meaning in the context. It is to be understood that the terms such as “including,” “having,” and “comprising” are intended to indicate the existence of the features, numbers, steps, actions, components, parts, ingredients, materials, or combinations thereof disclosed in the specification, and are not intended to preclude the possibility that one or more other features, numbers, steps, actions, components, parts, ingredients, materials, or combinations thereof may exist or may be added.

Whenever a range of values is enumerated, the range includes all values within the range as if recorded explicitly clearly, and may further include the boundaries of the range. Accordingly, the range of “X” to “Y” includes all values between X and Y, including X and Y. Further, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

The term “Cₓ-C_{y}” as used herein refers to a case where the number of carbon atoms constituting the substituent is x to y. For example, the term “C₁-C₆” refers to a case where the number of carbon atoms constituting the substituent is 1 to 6, and the term “C₆-C₂₀” refers to a case where the number of carbon atoms constituting the substituent is 6 to 20.

The term “monovalent hydrocarbon group” as used herein refers to a monovalent residue derived from an organic compound including carbon and hydrogen or a derivative of the organic compound, and examples thereof may include: a linear or branched alkyl group (e.g., a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, and a nonyl group); a monovalent saturated cyclic aliphatic hydrocarbon group (cycloalkyl group) (e.g., a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group); a monovalent unsaturated aliphatic hydrocarbon group (e.g., an alkenyl group, an alkynyl group, and an allyl group); a monovalent unsaturated cyclic aliphatic hydrocarbon group (cycloalkenyl group) (e.g., a 3-cyclohexenyl group); an aryl group (e.g., a phenyl group, a 1-napthyl group, and a 2-napthyl group); an arylalkyl group (e.g., a benzyl group and a diphenylmethyl group); a heteroatom-containing monovalent hydrocarbon group (e.g., a tetrahydrofuranyl group, a methoxymethyl group, an ethoxymethyl group, a methylthiomethyl group, an acetamidemethyl group, a trifluoroethyl group, a (2-methoxyethoxy)methyl group, an acetoxymethyl group, a 2-carboxyl-1-cyclohexyl group, a 2-oxopropyl group, a 4-oxo-1-adamantyl group, and a 3-oxocyclohexyl group); or any combination thereof. In addition, among these groups, some hydrogen atoms may be substituted with a moiety including a heteroatom, such as oxygen, sulfur, nitrogen, or a halogen atom, or some carbon atoms may be replaced by a moiety including a heteroatom, such as oxygen, sulfur, or nitrogen. Accordingly, these groups may each include a hydroxy group, a cyano group, a carbonyl group, a carboxyl group, an ether linkage, an ester linkage, a sulfonate ester linkage, a carbonate, a lactone ring, a sultone ring, a carboxylic anhydride moiety, or a haloalkyl moiety.

The term “divalent hydrocarbon group” as used herein refers to a divalent residue in which one hydrogen atom of the monovalent hydrocarbon group is replaced by a binding site to a neighboring atom. Examples of the divalent hydrocarbon group may include a linear or branched alkylene group, a cycloalkylene group, an alkenylene group, an alkynylene group, a cycloalkylene group, an arylene group, or a group in which some carbon atoms are replaced by a heteroatom.

The term “alkyl group” as used herein refers to a linear or branched saturated aliphatic hydrocarbon monovalent group, and examples thereof may include a methyl group, an ethyl group, a propyl group, an isobutyl group, a sec-butyl group, a tert-butyl group, a pentyl group, an iso-amyl group, a hexyl group, and the like. The term “alkylene group” as used herein refers to a linear or branched saturated aliphatic hydrocarbon divalent group, and examples thereof may include a methylene group, an ethylene group, a propylene group, a butylene group, an isobutylene group, and the like.

The term “halogenated alkyl group” as used herein refers to a group in which one or more substituents of an alkyl group are substituted with a halogen, and examples thereof may include CF₃ and the like. Here, the halogen may be F, Cl, Br, or I.

The term “alkoxy group” as used herein refers to a monovalent group having a formula of —OA₁₀₁, wherein A₁₀₁ is an alkyl group. Examples thereof may include a methoxy group, an ethoxy group, an isopropyloxy group, and the like.

The term “alkylthio group” as used herein refers to a monovalent group having a formula of —SA₁₀₁, wherein A₁₀ᵢ is an alkyl group.

The term “halogenated alkyl group” as used herein refers to a group in which one or more hydrogen atoms of an alkoxy group are substituted with a halogen, and examples thereof may include —OCF₃ and the like.

The term “halogenated alkylthio group” as used herein refers to a group in which one or more hydrogen atoms of an alkylthio group are substituted with a halogen, and examples thereof may include —SCF₃ and the like.

The term “cycloalkyl group” as used herein refers to a monovalent saturated hydrocarbon cyclic group, and examples thereof may include a monocyclic group, such as a cyclopropyl group, a cyclobutyl group, a cyclopentyl group, a cyclohexyl group, a cycloheptyl group, and the like, and a polycyclic condensed group, such as a norbornyl group, an adamantyl group, and the like. The term “cycloalkylene group” as used herein refers to a divalent saturated hydrocarbon cyclic group, and examples thereof include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, a dicyclohexylmethylene group, and/or the like.

The term “cycloalkoxy group” as used herein refers to a monovalent group having a formula of —OA₁₀₂, wherein A₁₀₂ is a cycloalkyl group. Examples thereof may include a cyclopropoxy group, a cyclobutoxy group, and the like.

The term “cycloalkylthio group” as used herein refers to a monovalent group having a formula of —SA₁₀₂, wherein A₁₀₂ is a cycloalkyl group.

The term “heterocycloalkyl group” as used herein refers to a group in which some carbon atoms of the cycloalkyl group are replaced by a moiety including a heteroatom, such as oxygen, sulfur, or nitrogen, and examples of the heterocycloalkyl group may include an ether linkage, an ester linkage, a sulfonate ester linkage, a carbonate, a lactone ring, a sultone ring, or a carboxylic anhydride moiety. The term “heterocycloalkylene group” as used herein refers to a group in which some carbon atoms of the cycloalkylene group are replaced by a moiety including a heteroatom, such as oxygen, sulfur, or nitrogen.

The term “heterocycloalkoxy group” as used herein refers to a monovalent group having a formula of —OA₁₀₃, wherein A₁₀₃ is a heterocycloalkyl group.

The term “alkenyl group” as used herein refers to a linear or branched unsaturated aliphatic monovalent hydrocarbon group including one or more carbon-carbon double bonds. The term “alkenylene group” as used herein refers to a linear or branched unsaturated aliphatic divalent hydrocarbon group including one or more carbon-carbon double bonds.

The term “cycloalkenyl group” as used herein refers to a monovalent unsaturated cyclic hydrocarbon group including one or more carbon-carbon double bonds. The term “cycloalkenylene group” as used herein refers to a divalent unsaturated cyclic hydrocarbon group including one or more carbon-carbon double bonds.

The term “heterocycloalkenyl group” as used herein refers to a group in which some carbon atoms of the cycloalkenylene group are replaced by a moiety including a heteroatom, such as oxygen, sulfur, or nitrogen. The term “heterocycloalkenylene group” as used herein refers to a group in which some carbon atoms of the cycloalkenylene group are replaced by a moiety including a heteroatom, such as oxygen, sulfur, or nitrogen.

The term “alkynyl group” as used herein refers to a linear or branched unsaturated aliphatic monovalent hydrocarbon including one or more carbon-carbon triple bonds.

The term “aryl group” as used herein refers to a monovalent group having a carbocyclic aromatic system, and examples thereof may include a phenyl group, a naphthyl group, an anthracenyl group, a phenanthrenyl group, a pyrenyl group, a chrysenyl group, and the like. The term “arylene group” as used herein refers to a divalent group having a carbocyclic aromatic system.

The term “heteroaryl group” as used herein refers to a monovalent group having a heterocyclic aromatic system, and examples thereof may include a pyridinyl group, a pyrimidinyl group, a pyrazinyl group, and the like. The term “heteroarylene group” as used herein refers to a divalent group having a heterocyclic aromatic system.

The term “substituent” as used herein may include: deuterium, a halogen, a hydroxyl group, a cyano group, a nitro group, a carbonyl group, a carboxylic acid group, an amino group, an ether moiety, an ester moiety, a sulfonate ester moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, or a C₁-C₂₀ heteroarylthio group; a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, or a C₁-C₂₀ heteroarylthio group, each substituted with deuterium, halogen, a hydroxyl group, a cyano group, a nitro group, a carbonyl group, a carboxylic acid group, an amino group, an ether moiety, an ester moiety, a sulfonate ester moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, a C₁-C₂₀ heteroarylthio group, or any combination thereof; and any combination thereof.

Hereinafter, the disclosure will be described in detail by explaining embodiments with reference to the accompanying drawings, and substantially identical or corresponding components are given the same reference numerals in the drawings, and thus a description thereof will be omitted. In the drawings, thicknesses are magnified to clearly illustrate various layers and regions. Also in the diagrams, thicknesses of some layers and regions are exaggerated for convenience of explanation. Meanwhile, embodiments described below are illustrative examples of embodiments, and various changes in forms and details may be made.

### [Photoreactive Polymer Compound]

An aspect of the disclosure provides a photoreactive polymer compound including a first repeating unit represented by Formula 1:

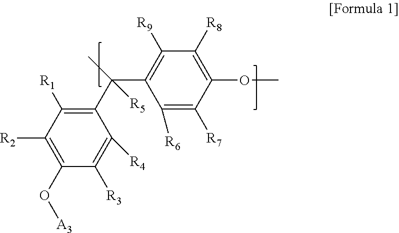

wherein, in Formula 1, A₃ and R₁ to R₉ may each independently be: hydrogen; deuterium; a halogen; a cyano group; a nitro group; a hydroxy group; a C₁-C₃₀ monovalent hydrocarbon group that optionally includes a heteroatom; or —N(Q₁)(Q₂).

In Formula 1, Q₁ and Q₂ may each independently be: hydrogen; deuterium; or a linear, branched, or cyclic C₁-C₂₀ monovalent hydrocarbon group that optionally includes a heteroatom.

The photoreactive polymer compound including the first repeating unit represented by Formula 1 may include at least one photosensitive group.

In at least one embodiment, the photoreactive polymer compound may include a photosensitive group on a main chain and/or a side chain.

For example, when the photoreactive polymer compound includes a photosensitive group on a main chain, (i) at least one of R₅ to R₉ and/or (ii) at least one terminal group of the first repeating unit may include the photosensitive group.

For example, when the photoreactive polymer compound includes a photosensitive group on a side chain, (i) A₃ and/or (ii) at least one of R₂ to R₄ may include a photosensitive group.

In at least one embodiment, (i) an A₃-O—* moiety in Formula 1, (ii) a terminal group binding to a carbon atom (e.g., a carbon atom to which R₅ is bonded) at the terminal of the first repeating unit represented by Formula 1, and/or (iii) an oxygen atom at the terminal of the first repeating unit represented by Formula 1 and a terminal group binding to the oxygen group may be a photosensitive group.

In at least one embodiment, the photosensitive group may be selected as to be reactive to visible light, ultraviolet (UV) rays, deep ultraviolet (DUV) rays, extreme ultraviolet (EUV) rays, electron beams (EBs), and/or X-rays.

In at least one embodiment, the photosensitive group may include an ester group, an amine group, a carbamate group, an acetamide group, a sulfonate group, a sulfate group, a sulfonamide group, an alkyl ether group, an allyl ether group, a silyl ether group, a benzyl ether group, a phenyl ether group, a phthalimide group, and/or a combination thereof.

In at least one embodiment, the photosensitive group may include a group represented by one of Formulae 3-1 to 3-27 and/or 5-1 to 5-31, as described in further detail below.

For example, the photosensitive group may be represented by Formula PG-1:

*—O—R_{A} [Formula PG-1]
wherein, in Formula PG-1,
R_{A} may be a group represented by one of Formulae 3-1 to 3-27 and 5-1 to 5-31 below, and
* indicates a binding site to a neighboring atom.

In at least one embodiment, the photoreactive polymer compound may be configured to undergo continuous depolymerization when exposed to light.

In at least one embodiment, the photoreactive polymer compound may comprise a polymer chain consist of a plurality of the first repeating unit or may further include other repeating units.

For example, in at least one embodiment, the photoreactive polymer compound may further include a second repeating unit represented by Formula 2:

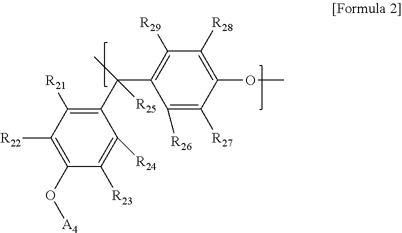

wherein, in Formula 2,
A₄ and R₂₁ to R₂₉ may each independently be: hydrogen; deuterium; a halogen; a cyano group; a hydroxy group; a C₁-C₃₀ monovalent hydrocarbon group that optionally includes a heteroatom; or —N(Q₃)(Q₄), and
Q₃ and Q₄ may each independently be: hydrogen; deuterium; or a C₁-C₃₀ monovalent hydrocarbon group that optionally includes a heteroatom.

In at least one embodiment, the first repeating unit and the second repeating unit may be different from each other.

In at least one embodiment, the photoreactive polymer compound may be represented by Formula 11 or 21:

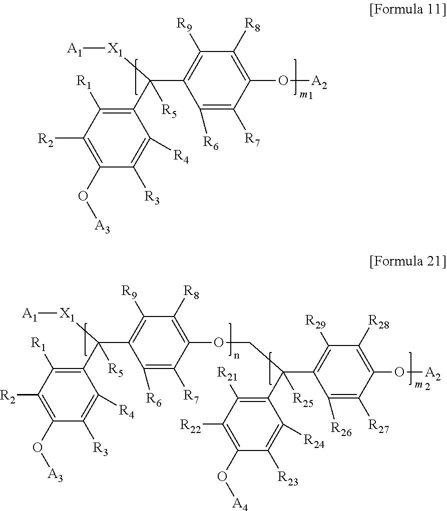

wherein, in Formulae 11 and 21,
X₁ may be O, S, Se, N(R₁₀), C(R₁₁)(R₁₂), or Si(R₁₃)(R₁₄),
A₁ to A₃ and R₁ to R₁₄ may each independently be: hydrogen; deuterium; a halogen; a cyano group; a hydroxy group; a linear, branched, or cyclic C₁-C₂₀ monovalent hydrocarbon group that optionally includes a heteroatom; or —N(Q₁)(Q₂),
A₄ and R₂₁ to R₂₉ may each independently be: hydrogen; deuterium; a halogen; a cyano group; a hydroxy group; a linear, branched, or cyclic C₁-C₂₀ monovalent hydrocarbon group that optionally includes a heteroatom; or —N(Q₃)(Q₄), wherein at least one of A₄ and R₂₁ to R₂₉ is different from a corresponding one of the A₃ and R₁ to R₁₄,
Q₁ to Q₄ may each independently be: hydrogen; deuterium; or a linear, branched, or cyclic C₁-C₂₀ monovalent hydrocarbon group that optionally includes a heteroatom, and
m1 and m2 may each independently be an integer from 2 to 10,000.

In at least one embodiment, at least one of A₁ to A₃ may be a C₁-C₂₀ alkyl group and/or a group represented by one of Formulae 3-1 to 3-27:

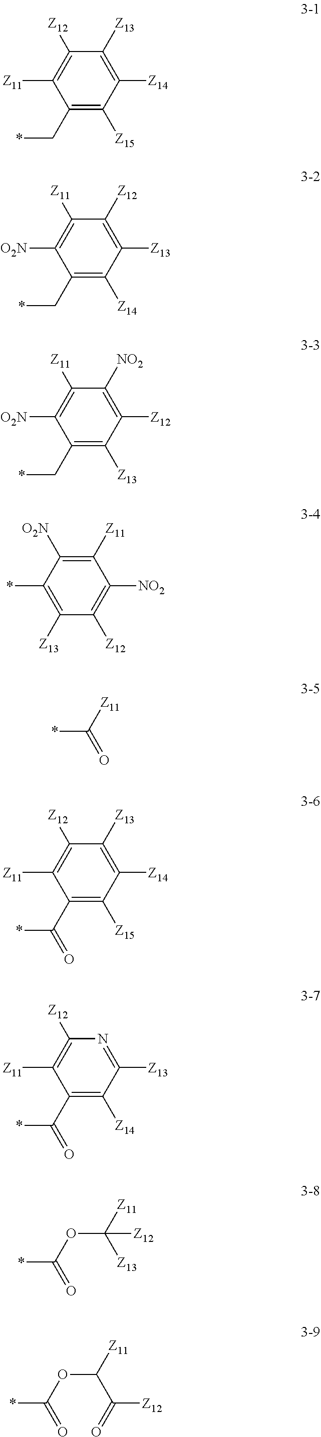

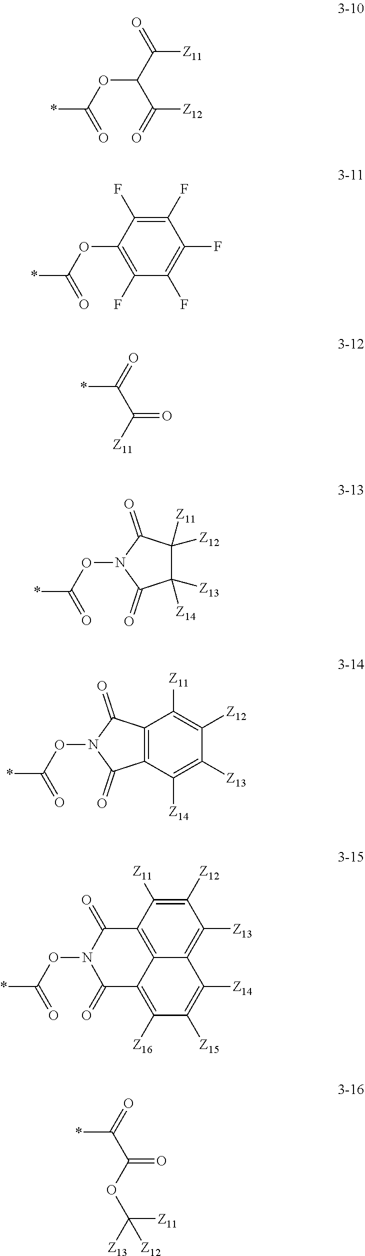

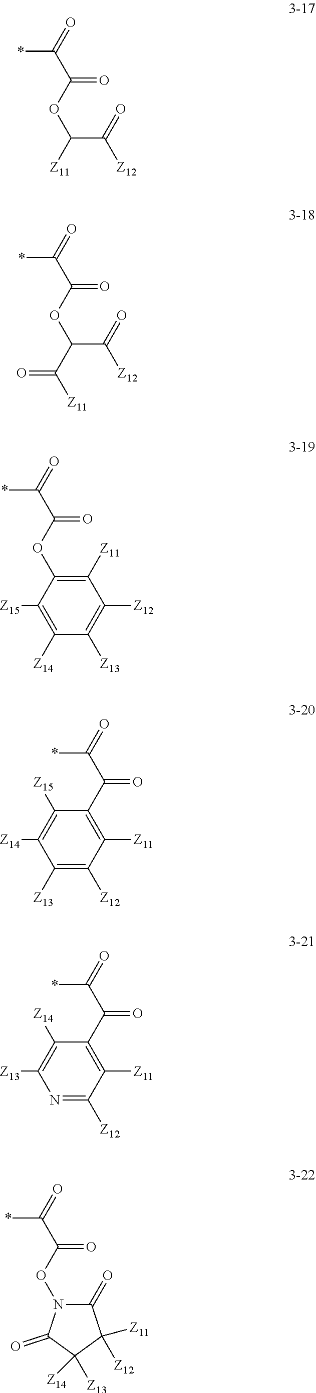

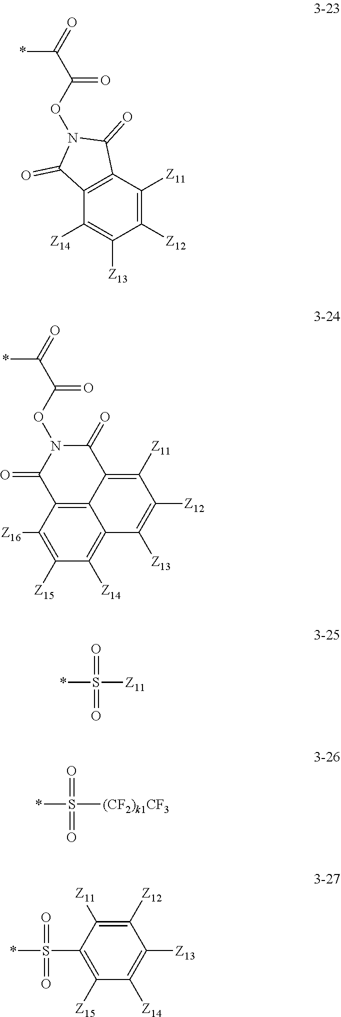

wherein, in Formulae 3-1 to 3-27,
Z₁₁ to Z₁₆ may each independently be: hydrogen, deuterium, a halogen, a hydroxyl group, a C₁-C₂₀ alkyl group, a C₁-C₂₀ fluoroalkyl group, a C₁-C₂₀ alkoxy group, a C₃-C₂₀ cycloalkyl group, a C₁-C₂₀ heterocycloalkyl group, a C₆-C₂₀ aryl group, a C₆-C₂₀ aryloxy group, a C₃-C₂₀ heteroaryl group, a C₃-C₂₀ heteroaryloxy group a C₁-C₂₀ alkyl group, a C₁-C₂₀ fluoroalkyl group, a C₁-C₂₀ alkoxy group, a C₃-C₂₀ cycloalkyl group, a C₁-C₂₀ heterocycloalkyl group, a C₆-C₂₀ aryl group, a C₆-C₂₀ aryloxy group, a C₃-C₂₀ heteroaryl group, or a C₃-C₂₀ heteroaryloxy group, each substituted with deuterium, a halogen, a hydroxyl group, a C₁-C₂₀ alkyl group, a C₁-C₂₀ fluoroalkyl group, a C₁-C₂₀ alkoxy group, a C₃-C₂₀ cycloalkyl group, a C₁-C₂₀ heterocycloalkyl group, a C₆-C₂₀ aryl group, a C₆-C₂₀ aryloxy group, a C₃-C₂₀ heteroaryl group, a C₃-C₂₀ heteroaryloxy group, and/or a combination thereof,
k1 may be an integer from 1 to 20, and
* indicates a binding site to a neighboring atom.

In at least one embodiment, A₃ may be a group represented by one of Formulae 3-1 to 3-27.

In at least one embodiment, an A₁-X₁—* moiety may be a group represented by one of Formulae 5-1 to 5-31:

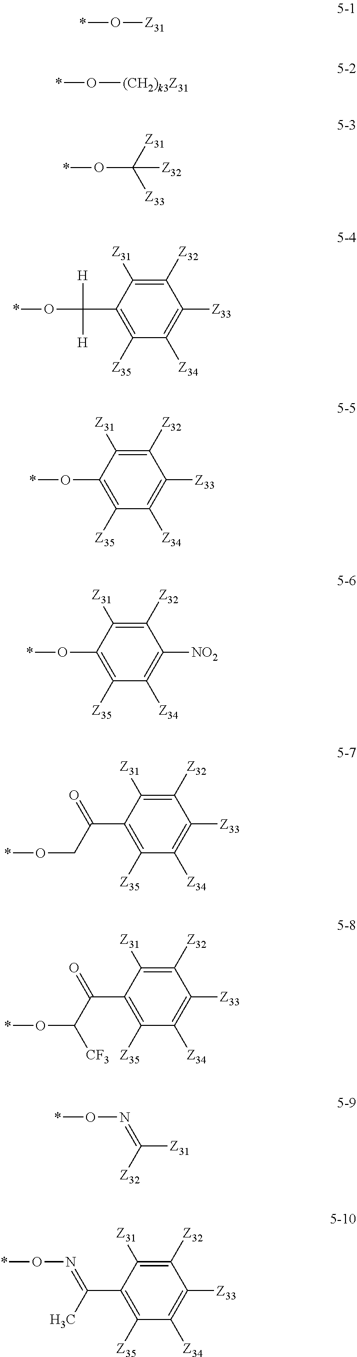

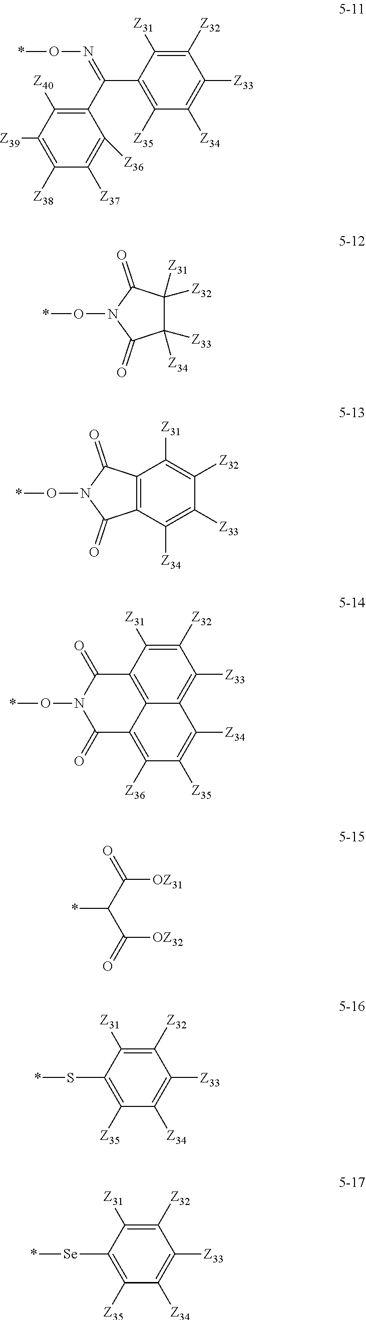

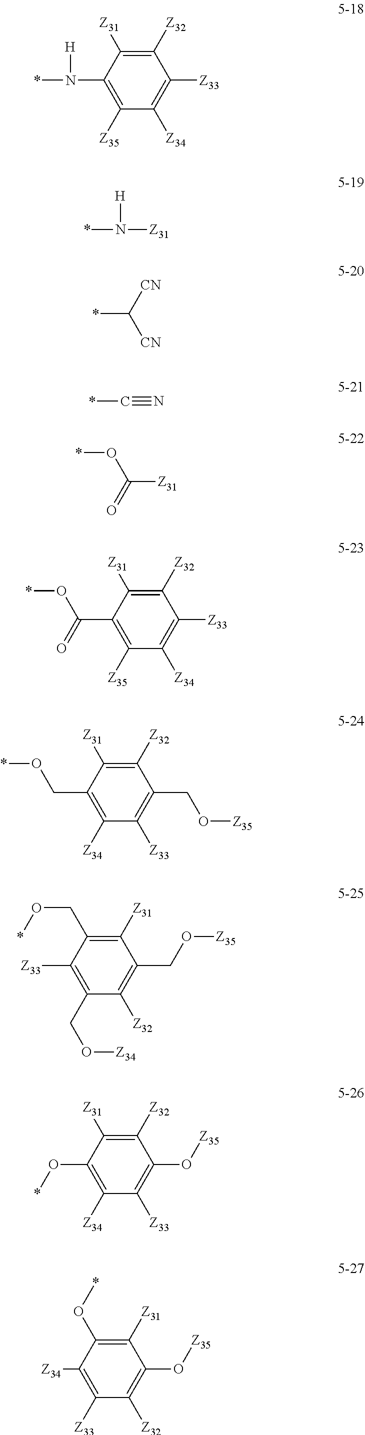

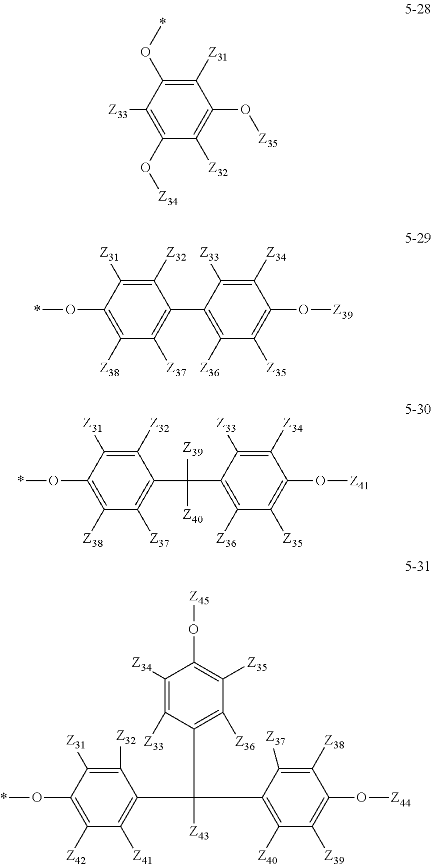

wherein, in Formulae 5-1 to 5-31,
Z₃₁ to Z₄₅ may each independently be: hydrogen, deuterium, a halogen, a hydroxyl group, a C₁-C₂₀ alkyl group, a C₁-C₂₀ fluoroalkyl group, a C₁-C₂₀ alkoxy group, a C₃-C₂₀ cycloalkyl group, a C₁-C₂₀ heterocycloalkyl group, a C₆-C₂₀ aryl group, a C₆-C₂₀ aryloxy group, a C₃-C₂₀ heteroaryl group, or a C₃-C₂₀ heteroaryloxy group; or

a C₁-C₂₀ alkyl group, a C₁-C₂₀ fluoroalkyl group, a C₁-C₂₀ alkoxy group, a C₃-C₂₀ cycloalkyl group, a C₁-C₂₀ heterocycloalkyl group, a C₆-C₂₀ aryl group, a C₆-C₂₀ aryloxy group, a C₃-C₂₀ heteroaryl group, or a C₃-C₂₀ heteroaryloxy group, each substituted with deuterium, a halogen, a hydroxyl group, a C₁-C₂₀ alkyl group, a C₁-C₂₀ fluoroalkyl group, a C₁-C₂₀ alkoxy group, a C₃-C₂₀ cycloalkyl group, a C₁-C₂₀ heterocycloalkyl group, a C₆-C₂₀ aryl group, a C₆-C₂₀ aryloxy group, a C₃-C₂₀ heteroaryl group, a C₃-C₂₀ heteroaryloxy group, and/or a combination thereof,
k3 may be an integer from 1 to 20, and
* indicates a binding site to a neighboring atom.

In at least one embodiment, the A₁-X₁—* moiety may be a group represented by one of structures of Group A1:

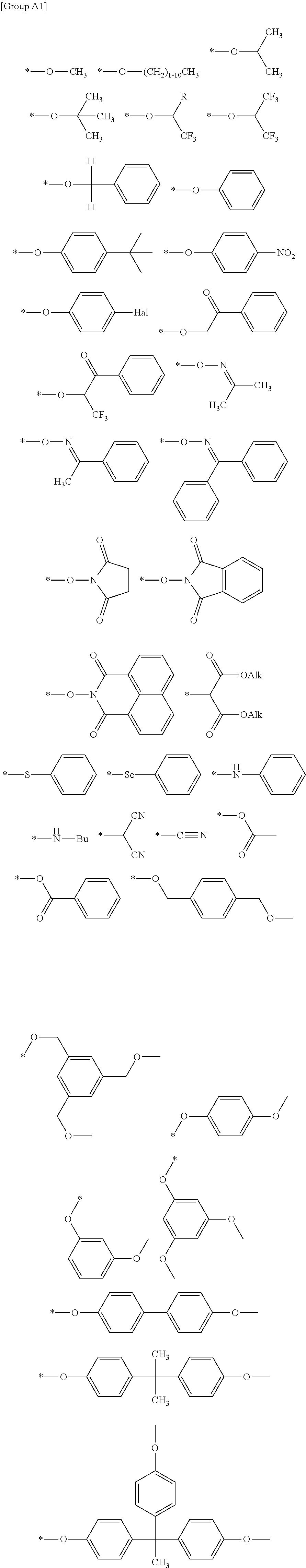

wherein, in the structures of Group A1,
Hal is a halogen,
Alk is a C₁-C₂₀ alkyl group,
Bu is a butyl group, and
* indicates a binding site to a neighboring atom.

In at least one embodiment, A₂ may be a group represented by one of structures of Group A2:

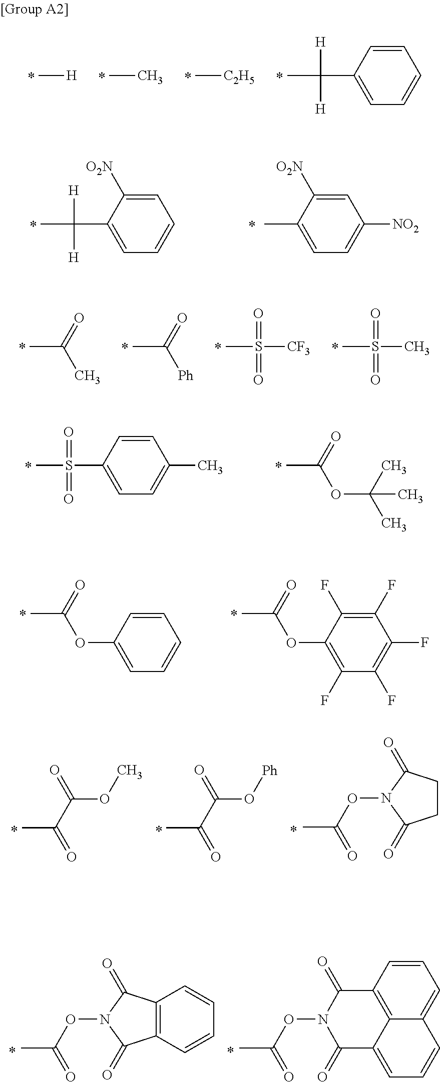

wherein, in the structures of Group A2,
Ph is a phenyl group, and
* indicates a binding site to a neighboring atom.

In at least one embodiment, A₃ and A₄ may each independently be a group represented by one of structures of Group A3:

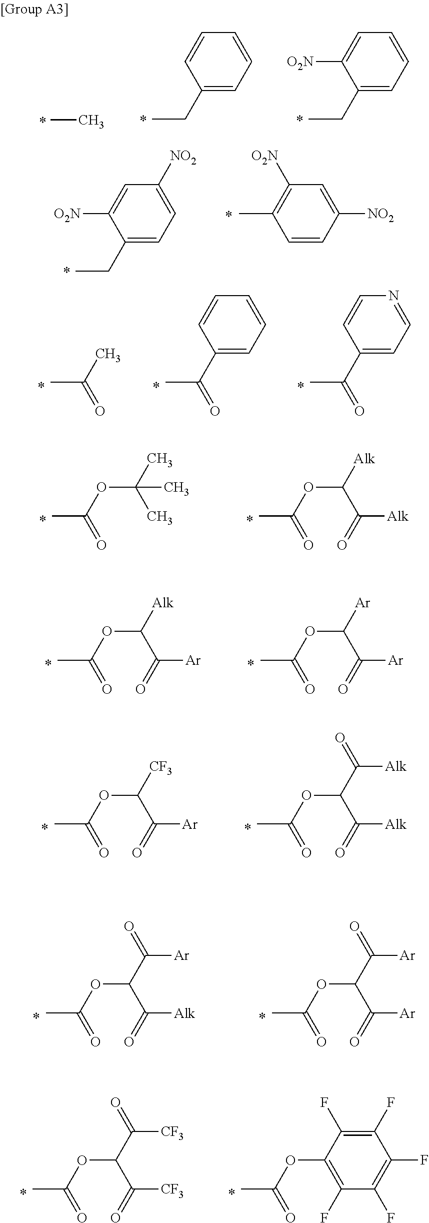

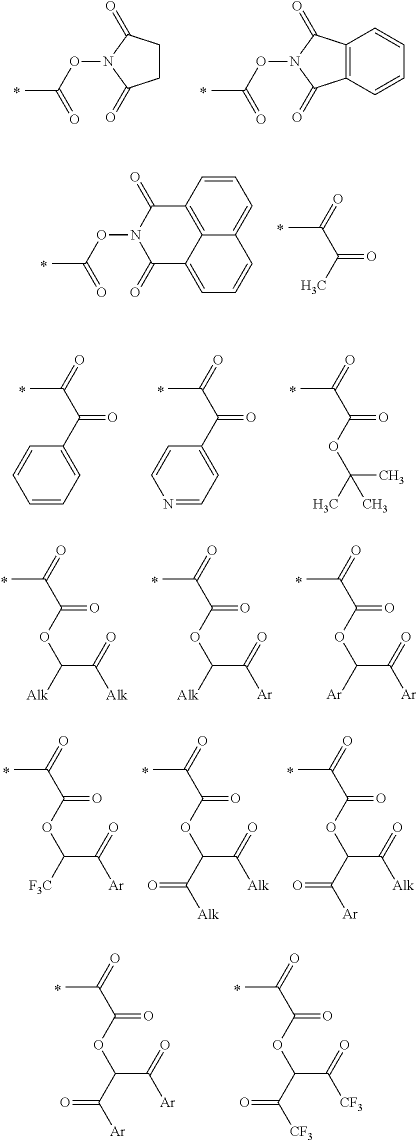

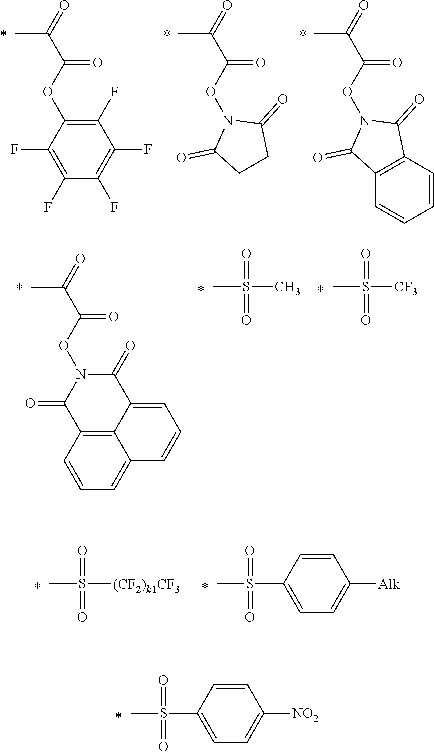

wherein, in the structures of Group A3,
Alk is a C₁-C₂₀ alkyl group,
Ar is a C₁-C₂₀ aryl group,
k1 is an integer from 1 to 20, and
* indicates a binding site to a neighboring atom.

In at least one embodiment, R₁ to R₁₄ and R₂₁ to R₂₉ may each independently be: one of hydrogen, deuterium, a halogen, a hydroxyl group, a C₁-C₂₀ alkyl group, a C₁-C₂₀ fluoroalkyl group, a C₁-C₂₀ alkoxy group, a C₃-C₂₀ cycloalkyl group, a C₁-C₂₀ heterocycloalkyl group, a C₆-C₂₀ aryl group, a C₆-C₂₀ aryloxy group, a C₃-C₂₀ heteroaryl group, or a C₃-C₂₀ heteroaryloxy group; or
one of a C₁-C₂₀ alkyl group, a C₁-C₂₀ fluoroalkyl group, a C₁-C₂₀ alkoxy group, a C₃-C₂₀ cycloalkyl group, a C₁-C₂₀ heterocycloalkyl group, a C₆-C₂₀ aryl group, a C₆-C₂₀ aryloxy group, a C₃-C₂₀ heteroaryl group, or a C₃-C₂₀ heteroaryloxy group, each substituted with deuterium, a halogen, a hydroxyl group, a C₁-C₂₀ alkyl group, a C₁-C₂₀ fluoroalkyl group, a C₁-C₂₀ alkoxy group, a C₃-C₂₀ cycloalkyl group, a C₁-C₂₀ heterocycloalkyl group, a C₆-C₂₀ aryl group, a C₆-C₂₀ aryloxy group, a C₃-C₂₀ heteroaryl group, a C₃-C₂₀ heteroaryloxy group, and/or a combination thereof.

In an embodiment, R₁ to R₁₄ and R₂₁ to R₂₉ may each independently be a group represented by one of structures of Group R1:

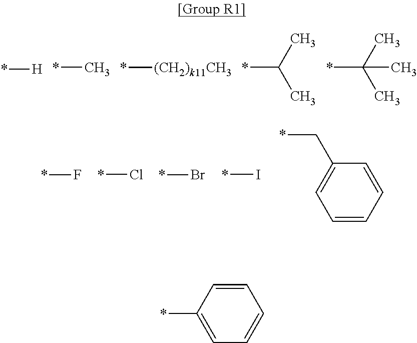

wherein, in the structures of Group R1,
k11 is an integer from 1 to 10, and
* indicates a binding site to a neighboring atom.

In at least one embodiment, R₅ and R₂₅ may each independently be a group represented by one of structures of Group R5:

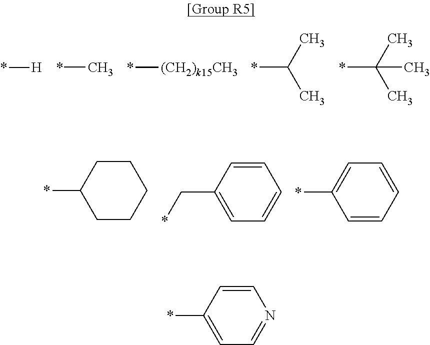

wherein, in the structures of Group R5,
k15 is an integer from 1 to 10, and
* indicates a binding site to a neighboring atom.

In at least one embodiment, m1 and m2 may each independently be included in the range of 2 to 5,000, 5 to 3,000, and/or 10 to 2,000.

In at least one embodiment, the photoreactive polymer compound may have a weight average molecular weight in a range of about 3,000 g/mol to about 30,000 g/mol, about 3,500 g/mol to about 20,000 g/mol, and/or about 4,000 g/mol to about 10,000 g/mol.

In at least one embodiment, the 5% mass-loss temperature (T_{d5%}) of the photoreactive polymer compound may be 150° C. or more. For example, the 5% mass-loss temperature T_{d5%} of the photoreactive polymer compound may be in a range of about 160° C. to about 300° C., about 170° C. to about 250° C., and/or about 180° C. to about 230° C.

In at least one embodiment, the photoreactive polymer compound may be represented by one of Formulae P1 to P5:

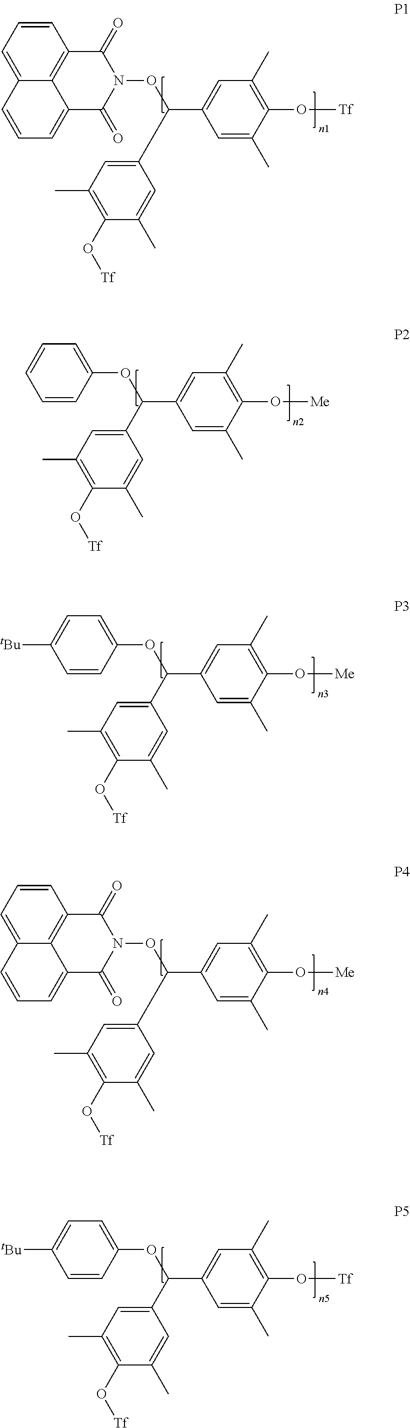

wherein, in Formulae P1 to P5,
Tf is a triflate (and/or trifluoromethanesulfonate) group,
Me is a methyl group,
^{t}Bu is a tert-butyl group, and
n1 to n5 may independently be an integer from 2 to 10,000.

In at least one embodiment, n1 to n5 may each independently be included in a range of 2 to 5,000, 5 to 3,000, or 10 to 2,000.

The photoreactive polymer compound represented by Formula 1 may have excellent sensitivity to light exposure, a low polydispersity index (PDI), and excellent thermal stability.

For example, the photoreactive polymer compound represented by Formula 1 has excellent sensitivity to EUV rays, and thus may efficiently obtain a high-resolution pattern with low line edge roughness (LER) when applied to a photoresist.

In addition, the photoreactive polymer compound has a low PDI, and thus may have excellent solubility in a solvent and accordingly form a high-quality thin film.

Therefore, using a resist composition including the photoreactive polymer compound represented by Formula 1 may be advantageous for lithography applications since the processing temperature ranges may be expanded in various process steps.

In addition, the properties of the photoreactive polymer compound may be controlled by appropriately selecting the molecular weight and structure. For example, by appropriately selecting the substituents of Formulae 11 and 12 (e.g., A₁ to A₄, R₁ to R₁₄, and R₂₁ to R₂₉, and/or m1 and m2 for the repeating units) desired physical properties may be easily achieved.

In this regard, a photoresist composition including the photoreactive polymer compound according to at least one embodiment may have excellent properties such as improved developability and/or improved resolution, etc.

In at least one embodiment, the photoreactive polymer compound may comprise a polymer chain consist of the first repeating unit represented by Formula 1 or the first repeating unit represented by Formula 1 and a second repeating unit represented by Formula 2.

In at least one embodiment, the photoreactive polymer compound may comprise a polymer chain consist of the first repeating unit represented by Formula 1. For example, the photoreactive polymer compound may not include the second repeating unit represented by Formula 2.

In at least one embodiment, the photoreactive polymer compound may have a weight average molecular weight (Mw) in a range of about 1,000 to about 1,000,000, about 2,000 to 500,000, and/or about 3,000 to 200,000, as measured by, e.g., gel permeation chromatography using tetrahydrofuran as a solvent and polystyrene as a standard material.

In at least one embodiment, the photoreactive polymer compound may have a polydispersity index (PDI_(Mw/Mn)) in a range of about 1 to about 2, about 1 to about 1.5, about 1 to about 1.3, about 1 to about 1.25, and/or about 1 to about 1.2. When PDI of the photoreactive polymer compound is satisfied within these ranges, the dispersibility and/or compatibility of the photoreactive polymer compound may be easily controlled, the possibility of foreign substances remaining on a pattern may be reduced, or deterioration of a pattern profile may be minimized. Accordingly, a photoresist composition including the photoreactive polymer compound may become more suitable for forming a fine pattern.

The photoreactive polymer compound may be prepared by a suitable method, for example, by dissolving unsaturated bond-containing monomer(s) in an organic solvent, followed by anionic polymerization using an organic base.

In at least one embodiment, when the photoreactive polymer compound further includes the second repeating unit represented by Formula 2, the mole fraction (mol %) of each repeating unit derived from each monomer may be as follows, but embodiments are not limited thereto:
i) the mole fraction mol % of the first repeating unit represented by Formula 1 in the photoreactive polymer may be in a range of about 10 mol % to 99 mol %, about 20 mol % to about 95 mol %, about 30 mol % to about 90 mol %, about 40 mol % to about 70 mol %, about 50 mol % to about 60 mol %, about 1 mol % to about 80 mol %, about 2 mol % to about 70 mol %, about 5 mol % to about 50 mol %, or about 10 mol % to about 40 mol %; and
ii) the mole fraction mol % of the second repeating unit represented by Formula 2 in the photoreactive polymer, may be in a range of about 1 mol % to about 80 mol %, about 2 mol % to about 70 mol %, about 5 mol % to about 50 mol %, or about 10 mol % to about 40 mol %.

In at least one embodiment, the photoreactive polymer compound may be a random copolymer, a block copolymer, an alternating copolymer, a graft copolymer, or a combination thereof, each including the first repeating unit and the second repeating unit.

The structure (composition) of the photoreactive polymer compound may be confirmed by performing FT-IR analysis, NMR analysis, X-ray fluorescence (XRF) analysis, mass spectrometry, UV analysis, single crystal X-ray structure analysis, powder X-ray diffraction (PXRD) analysis, liquid chromatography (LC) analysis, size exclusion chromatography (SEC) analysis, thermal analysis, and the like. Details on such confirmation methods are the same as described in Examples below.

### [Photoresist Composition]

Another aspect of the disclosure provides a photoresist composition including the photoreactive polymer compound.

A base resin commonly used in the photoresist composition may have a low line edge roughness (LER) due to a high PDI, chain entanglement, low compatibility with photoacid generators and/or solvents, and/or the like, and, in this regard, the base resin may have a difficulty achieving a high-resolution pattern.

As described above, the photoreactive polymer compound including the repeating unit represented by Formula 1 may have excellent sensitivity to light exposure, a low PDI, and excellent thermal stability.

In this regard, the photoresist composition according to at least one embodiment may have excellent properties such as improved developability and/or improved resolution, and/or the like.

The photoresist composition according to at least one embodiment may not include a photoacid generator. In this regard, the photoresist composition may have a reduced LER so that a pattern resolution may be improved accordingly.

The solubility of the photoresist composition in a developing solution may change upon exposure to high-energy rays. The photoresist composition may be a positive photoresist composition that forms a positive photoresist pattern after an exposed area of a photoresist film is dissolved and removed or a negative photoresist composition that forms a negative photoresist pattern after an unexposed area of a photoresist film is dissolved and removed. In addition, a sensitive photoresist composition according to an embodiment may be for an alkali development process using an alkali developing solution for development treatment in the formation of a photoresist pattern, or may be for a solvent development process using a developing solution containing an organic solvent (hereinafter also referred to as an organic developing solution) for the development treatment.

In at least one embodiment, the photoresist composition may be a positive tone photoresist composition.

In at least one embodiment, the photoresist composition may be a non-chemically amplified (non-CA) type.

In at least one embodiment, the amount of the photoreactive polymer compound may be in a range of about 0.01 parts by weight to about 99 parts by weight based on 100 parts by weight of the photoresist composition. For example, the amount of the photoreactive polymer compound may be, based on 100 parts by weight of the photoresist composition, about 0.05 parts by weight to about 70 parts by weight, about 0.1 parts by weight to about 50 parts by weight, about 0.5 parts by weight to about 40 parts by weight, about 1 part by weight to about 20 parts by weight, or about 2 parts by weight to about 10 parts by weight.

In at least one embodiment, the photoresist composition may further include at least one of an organic solvent, a base resin, a photoacid generator, and a photodegradable quencher.

In at least one embodiment, the photoresist composition may not further include a base resin. That is, the photoreactive polymer compound may serve as a base resin in the photoresist composition, and in this case, the photoresist composition may not include a separate base resin other than the photoreactive polymer compound.

The photoreactive polymer compound is the same as described above, and thus a description thereof will be omitted, and an organic solvent, a base resin, a photoacid generator, and optional components included as necessary will be described below. In at least one embodiment, as the photoreactive polymer compound including the repeating unit represented by Formula 1 for use in the photoresist composition, one type or a combination of two or more different types of the photoreactive polymer compound may be used.

### <Organic Solvent>

An organic solvent included in the photoresist composition may be selected based on a capability of dissolving or dispersing the photoreactive polymer compound, the base resin, the photoacid generator, and optional components contained as necessary. One type of the organic solvent may be used, or a combination of two or more different types of the organic solvent may be used. In addition, a mixed solvent in which water and the organic solvent are mixed may be used.

Examples of the organic solvent may include an alcohol-based solvent, an ether-based solvent, a ketone-based solvent, an amide-based solvent, an ester-based solvent, a sulfoxide-based solvent, a hydrocarbon-based solvent, and the like.

Specific examples of the alcohol-based solvent may include: a monoalcohol-based solvent, such as methanol, ethanol, n-propanol, isopropanol, 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxybutanol, n-hexanol, 2-methylpentanol, sec-hexanol, 2-ethylbutanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, diacetone alcohol, and the like; a polyhydric alcohol-based solvent, such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, and the like; a polyhydric alcohol-containing ether-based solvent, such as ethyleneglycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, diethylene glycol dimethyl ether, propylene glycol monomethyl ether, propylene glycol dimethyl ether, propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, and the like; and/or the like.

Examples of the ether-based solvent may include: a dialkyl ether-based solvent (such as diethyl ether, dipropyl ether, dibutyl ether, and/or the like); a cyclic ether-based solvent (such as tetrahydrofuran, tetrahydropyran, and/or the like); an aromatic ring-containing ether-based solvent (such as diphenyl ether, anisole, and/or the like); and/or the like.

Examples of the ketone-based solvent may include: a chain ketone solvent (such as acetone, methylethylketone, methyl-n-propyl ketone, methyl-n-butyl ketone, methyl-n-pentyl ketone, diethyl ketone, methyl isobutyl ketone, 2-heptanone, ethyl-n-butyl ketone, methyl-n-hexy ketone, diisobutyl ketone, trimethyl nonanone, and/or the like); a cyclic ketone-based solvent (such as cyclopentanone, cyclohexanone, cycloheptanone, cyclooctanone, methylcyclohexanone, and/or the like); 2,4-pentandione; acetonyl acetone; acetphenone; and/or the like.

Examples of the amide-based solvent may include: a cyclic amide-based solvent (such as N,N′-dimethylimidazolidinone, N-methyl-2-pyrrolidone, and/or the like); a chain amide-based solvent (such as N-methylformamide, N,N-dimethylformamide, N,N-diethylformamide, acetamide, N-methylacetamide, N,N-dimethylacetamide, N-methylpropionamide, and/or the like); and/or the like.

Examples of the ester-based solvent may include: an acetate ester-based solvent (such as methyl acetate, ethyl acetate, n-propyl acetate, isopropyl acetate, n-butyl acetate, isobutyl acetate, sec-butyl acetate, t-butyl acetate, n-pentyl acetate, isopentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, and/or the like); a polyhydric alcohol-containing ether carboxylate-based solvent (such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, and the like; a lactone-based solvent, such as γ-butylolactone, δ-valerolactone, and/or the like); a carbonate-based solvent (such as dimethyl carbonate, diethyl carbonate, ethylene carbonate, propylene carbonate, and/or the like); a lactate ester-based solvent (such as methyl lactate, ethyl lactate, n-butyl lactate, n-amyl lactate, and/or the like); glycoldiacetate, methoxytriglycol acetate, propionic acid ethyl, propionic acid n-butyl, propionic acid isoamyl, diethyloxalate, di-n-butyloxalate, methyl acetoacetate, ethyl acetoacetate, malonic acid diethyl, phthalic acid dimethyl, phthalic diethyl, and/or the like.

Examples of the sulfoxide-based solvent may include dimethyl sulfoxide, diethyl sulfoxide, and/or the like.

Examples of the hydrocarbon-based solvent may include: an aliphatic hydrocarbon-based solvent (such as n-pentane, isopentane, n-hexane, isohexane, n-heptane, isoheptane, 2,2,4-trimethyl pentane, n-octane, isooctane, cyclohexane, methylcyclohexane, and/or the like); an aromatic hydrocarbon-based solvent (such as benzene, toluene, xylene, mesitylene, ethyl benzene, trimethyl benzene, methylethyl benzene, n-propyl benzene, isopropyl benzene, diethyl benzene, isobutyl benzene, triethyl benzene, diisopropyl benzene, n-amylnaphthalene, and/or the like); and/or the like.

In at least one embodiment, the organic solvent may be selected from an alcohol-based solvent, an amide-based solvent, an ester-based solvent, a sulfoxide-based solvent, and/or a combination thereof. In one or more embodiments, the organic solvent may be selected from propylene glycol monomethyl ether, propylene glycol monoethyl ether, propylene glycol monomethyl ether acetate, N-methyl-2-pyrrolidone, N,N-dimethylacetamide, ethyl lactate, dimethyl sulfoxide, and a combination thereof.

In at least one embodiment, when an acetal-type acid labile group is used, the organic solvent may further include alcohol having a high boiling point, such as diethylene glycol, propylene glycol, glycerol, 1,4-butanediol, or 1,3-butanediol, to accelerate a deprotection reaction of acetal.

The amount of the organic solvent may be in a range of about 200 parts by weight to about 5,000 parts by weight, for example, about 400 parts by weight to about 3,000 parts by weight, based on 100 parts by weight of the base resin.

### <Base Resin>

In at least one embodiment, the photoresist composition may further include a base resin that is different from the photoreactive polymer compound.

The base resin may include a repeating unit represented by Formula 5 and including an acid labile group:

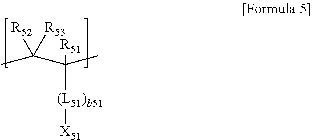

The base resin including the repeating unit represented by Formula 5 may be decomposed under the action of an acid to generate a carboxyl group, thereby being converted to have alkali solubility.

The base resin may further include, in addition to the repeating unit represented by Formula 5, a repeating unit represented by Formula 4:

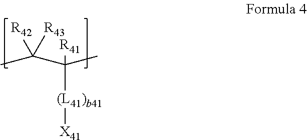

wherein, in Formulae 4 and 5,
L₄₁ and L₅₁ may each independently be a single bond, a substituted or unsubstituted C₁-C₁₀ alkylene group, a substituted or unsubstituted C₃-C₁₀ cycloalkylene group, a substituted or unsubstituted C₃-C₁₀ heterocycloalkylene group, a substituted or unsubstituted phenylene group, a substituted or unsubstituted naphthylene group, *—O—*′, *—C(═O)O—*′, —OC(═O)—*′, *—C(═O)NH—*′, —NHC(═O)—*′, or any combination thereof,
b41 and b51 may each independently be 1, 2, 3, 4, 5, or 6,
R₄₁ to R₄₃ and R₅₁ to R₅₃ may each independently be: hydrogen; deuterium; a halogen; a cyano group; a hydroxy group; a linear, branched, or cyclic C₁-C₂₀ monovalent hydrocarbon group that optionally includes a heteroatom; or —N(Q₁)(Q₂),
X₄₁ may be: hydrogen; deuterium; a halogen; a cyano group; a hydroxy group; a C₁-C₂₀ alkoxy group; a linear, branched, or cyclic C₁-C₂₀ monovalent hydrocarbon group that optionally includes a heteroatom; or —N(Q₁)(Q₂), and
X₅₁ may be an acid labile group.

Like in Formula 1, in Formulae 4 and 5, Q₁ and Q₂ may each independently be: hydrogen; deuterium; or a linear, branched, or cyclic C₁-C₂₀ monovalent hydrocarbon group that optionally includes a heteroatom.

In at least one embodiment, the repeating unit represented by Formula 4 may be represented by Formula 4-1:

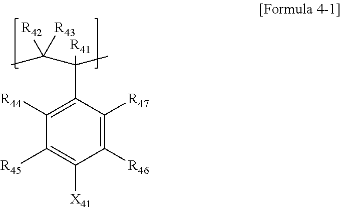

wherein, in Formula 4-1,
R₄₁ to R₄₃ and X₄₁ may each be the same as described herein, and
R₄₄ to R₄₇ may each independently be: hydrogen; deuterium; a halogen; a cyano group; a hydroxy group; a C₁-C₂₀ alkoxy group; or a linear, branched, or cyclic C₁-C₂₀ monovalent hydrocarbon group that optionally includes a heteroatom.

In at least one embodiment, X₄₁ may be a non-acid labile group.

In at least one embodiment, the repeating unit represented by Formula 5 may be represented by Formula 5-1:

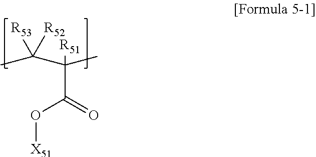

wherein, in Formula 5-1,
R₅₁ to R₅₃ and X₅₁ may each be the same as described herein.

In at least one embodiment, the acid labile group may be represented by one of Formulae 6-1 to 6-12:

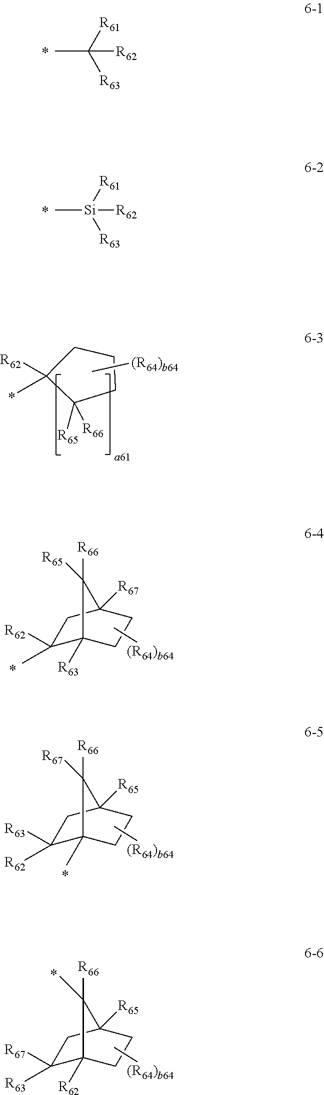

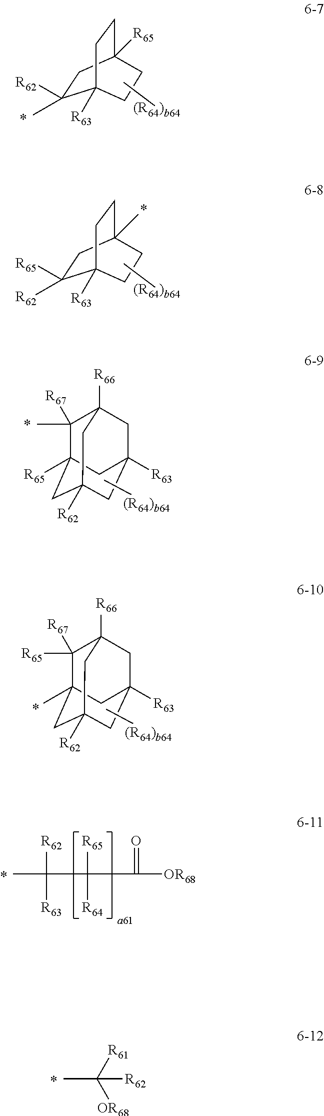

wherein, in Formulae 6-1 to 6-12,
a61 may be an integer from 0 to 6,
R₆₁ to R₆₇ may each independently be hydrogen or a linear, branched, or cyclic C₁-C₂₀ monovalent hydrocarbon group that optionally includes a heteroatom,
R₆₈ may be a linear, branched, or cyclic C₁-C₂₀ monovalent hydrocarbon group that optionally includes a heteroatom,
two adjacent groups of R₆₁ to R₆₈ may optionally be bonded to each other to form a ring,
b64 may be an integer from 0 to 6, and * indicates a binding site to a neighboring atom.

In at least one embodiment, the acid labile group may be selected from Group II:

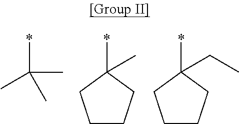

wherein, in Group II,
* indicates a binding site to a neighboring atom.

For example, in ArF lithography processes, X₄₁ may include a lactone ring as a polar moiety, and in KrF, EB, and EUV lithography processes, X₄₁ may be phenol.

In at least one embodiment, the base resin may not include a moiety including an anion and/or a cation.

The base resin may have a weight average molecular weight Mw in a range of about 1,000 to 500,000, for example, about 3,000 to about 100,000, as measured by gel permeation chromatography using tetrahydrofuran as a solvent and polystyrene as a standard material.

The base resin may have a PDI (Mw/Mn) in a range of about 1.0 to about 3.0, for example, about 1.0 to about 2.0. When the PDI is within these ranges, the possibility of foreign substances remaining on the pattern may be lowered, or deterioration of a pattern profile may be minimized. Accordingly, the photoresist composition may become more suitable for forming a fine pattern.

The base resin may be prepared by any suitable method, for example, by dissolving unsaturated bond-containing monomer(s) in an organic solvent, followed by thermal polymerization in the presence of a radical initiator.

In the base resin, a mole fraction mol % of each repeating unit derived from each monomer may be as follows, but embodiments are not limited thereto:
i) a mole fraction mol % of the repeating unit represented by Formula 5 may be in a range of about 1 mol % to about 60 mol %, about 5 mol % to about 50 mol %, and/or about 10 mol % to about 50 mol %; and
ii) a mole fraction mol % of the repeating unit represented by Formula 4 may be in a range of about 40 mol % to about 99 mol %, about 50 mol % to about 95 mol %, and/or about 50 mol % to about 90 mol %.

The base resin may be a homopolymer, or may include a mixture of two or more types of polymers having a different composition, a different weight average molecular weight, and/or a different PDI.

### <Photoacid Generator>

The photoresist composition according to at least one embodiment may not include a photoacid generator. In this regard, the photoresist composition may have a reduced LER, and the pattern resolution may be improved accordingly.

In an alternative embodiment, the photoresist composition may further include a photoacid generator.

The photoacid generator may include any compound capable of generating an acid upon exposure to high-energy rays, such as UV rays, DUV rays, EBs, EUV rays, X-rays, excimer lasers, γ-rays, and/or the like.

The photoacid generator may include a sulfonium salt, an iodonium salt, a combination thereof, and/or the like.

In at least one embodiment, the photoacid generator may be represented by Formula 7:

B₇₁⁺A₇₁⁻ [Formula 7]
wherein, in Formula 7,
B₇₁⁺ may be represented by Formula 7A, and A₇₁⁻ may be represented by one of Formulae 7B to 7D, and
B₇₁⁺ and A₇₁⁻ may optionally be linked to each other via a carbon-carbon covalent bond:

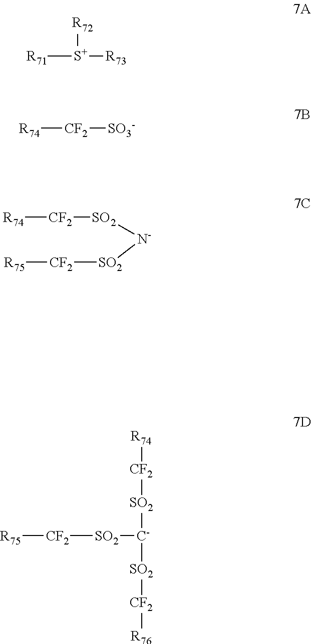

wherein, in Formulae 7A to 7D,
R₇₁ to R₇₃ may each independently be a linear, branched, or cyclic C₁-C₂₀ monovalent hydrocarbon group,
adjacent two groups of R₇₁ to R₇₃ may optionally be bonded to each other to form a ring, and
R₇₄ to R₇₆ are each independently: F; or a linear, branched, or cyclic C₁-C₂₀ monovalent hydrocarbon group that optionally includes a heteroatom.

In Formula 7A, R₇₁ to R₇₃ may each be the same as described in connection with R₃₁ to R₃₅ in Formula 3-1.

Regarding the descriptions of R₇₄ to R₇₆ in Formulae 7B to 7D, the monovalent hydrocarbon may include: for example, a linear or branched alkyl group (e.g., a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, a nonyl group, an undecyl group, a tridecyl group, a pentadecyl group, a heptadecyl group, and an eicosanyl group); a monovalent saturated alicyclic hydrocarbon group (e.g., a cyclopentyl group, a cyclohexyl group, a 1-adamantyl group, a 2-adamantyl group, a 1-adamantylmethyl group, a norbornyl group, a norbornylmethyl group, a tricyclotricyclodecanyl group, a tetracyclododecanyl group, a tetracyclododecanylmethyl group, and a dicyclohexylmethyl group); a monovalent unsaturated aliphatic hydrocarbon group (e.g., an aryl group and a 3-cyclohexenyl group); an aryl group (e.g., a phenyl group, a 1-naphthyl group, and a 2-naphthyl group); an arylalkyl group (e.g., a benzyl group and a diphenylmethyl group); and a heteroatom-containing monovalent hydrocarbon group (e.g., a tetrahydrofuranyl group, a methoxymethyl group, an ethoxymethyl group, a methylthiomethyl group, an acetamidemethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group); and/or the like. In addition, among these groups, some hydrogen atoms may be substituted with a moiety including a heteroatom, such as oxygen, sulfur, nitrogen, or a halogen atom, or some carbon atoms may be replaced by a moiety including a heteroatom, such as oxygen, sulfur, or nitrogen. Accordingly, these groups may each include a hydroxy group, a cyano group, a carbonyl group, a carboxyl group, an ether linkage, an ester linkage, a sulfonate ester linkage, a carbonate, a lactone ring, a sultone ring, a carboxylic anhydride moiety, or a haloalkyl moiety.

For example, in Formula 7, B₇₁⁺ may be represented by Formula 7A, and A₇₁⁻ may be represented by Formula 7B. In detail, R₇₁ to R₇₃ in Formula 7A may each be a phenyl group, and R₇₄ in Formula 7B may be a propyl group substituted with F.

The photoacid generator may be included in the amount in a range of about 0 parts by weight to about 40 parts by weight, about 0.1 parts by weight to about 40 parts by weight, or about 0.1 parts by weight to about 20 parts by weight, based on 100 parts by weight of the base resin. When the amount of the photoacid generator is satisfied within these ranges, proper resolution may be achieved, and problems related to foreign substances after development or during stripping may be reduced.

One type of the photoacid generator may be used, or a combination of two or more different types of the photoacid generator may be used.

### <Photodegradable Quencher>

A photodegradable quencher may be a salt that generates an acid having weaker acidity than an acid generated from the photoreactive polymer compound and/or the photoacid generator.

The photodegradable quencher may include an ammonium salt, a sulfonium salt, an iodonium salt, or a combination thereof.

In an embodiment, the photodegradable quencher may be represented by Formula 8:

B₈₁⁺A₈₁⁻ Formula 8
wherein, in Formula 8,
B₈₁⁺ may be represented by one of Formulae 8A to 8C, and A₈₁⁻ may be represented by one of Formulae 8D to 8F, and
B₈₁⁺ and A₈₁⁻ may optionally be linked to each other via a carbon-carbon covalent bond:

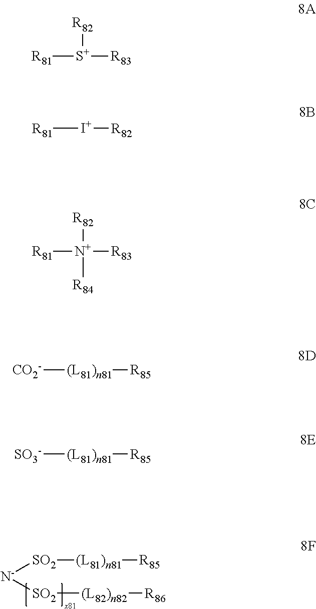

wherein, in Formulae 8A to 8F,
L₈₁ and L₈₂ may each independently be a single bond or CRR′,
n81 and n82 may each independently be 1, 2, or 3,
x81 may be 0 or 1,
R₈₁ to R₈₄ may each independently be a linear, branched, or cyclic C₁-C₂₀ monovalent hydrocarbon group,
adjacent two groups of R₈₁ to R₈₄ may optionally be bonded to each other to form a ring, and
R₈₅ and R₈₆ may each independently be: hydrogen; a halogen; or a linear, branched, or cyclic C₁-C₂₀ monovalent hydrocarbon group which may optionally include a heteroatom.

The photodegradable quencher may be included in the amount in a range of about 0.001 parts by weight to about 20 parts by weight, about 0.005 parts by weight to about 10 parts by weight, about 0.01 parts by weight to about 5 parts by weight, about 0.05 parts by weight to about 2 parts by weight, about 0.1 parts by weight to about 1 part by weight, and/or about 0.2 parts by weight to about 0.5 parts by weight, based on 100 parts by weight of the photoresist composition. When the amount of the photodegradable quencher is satisfied within these ranges, proper resolution may be achieved, and problems related to foreign substances after development or during stripping may be reduced.

One type of the photodegradable quencher may be used, or a combination of two or more different types of the photodegradable quencher may be used.

### <Optional Components>

The photoresist composition may further include a surfactant, a cross-linking agent, a leveling agent, a colorant, or a combination thereof, as necessary.

For example, the photoresist composition may further include a surfactant to improve coating properties, developability, and/or the like. Examples of the surfactant may include: a non-ionic surfactant, such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, polyethylene glycol distearate, and the like; and the like. For use as the surfactant, a commercially available product may be used, or a synthetic product may be used. Examples of the commercially available surfactant may include KP341 (manufactured by Shin-Etsu Chemical Co., Ltd.), POLYFLOW No. 75 and POLYFLOW No. 95 (manufactured by Kyoeisha Chemical Co., Ltd.), FTOP EF301, FTOP EF303, and FTOP EF352 (manufactured by Mitsubishi Materials Electronic Chemicals Co., Ltd.), MEGAFACE F171 (registered trademark), MEGAFACE F173, R40, R41, and R43 (manufactured by DIC Corporation), Fluorad FC430 (registered trademark) and Fluorad FC431 (manufactured by 3M Company), AsahiGuard AG710 (product of AGC Corporation), Surflon S-382 (registered trademark), Surflon SC-101, Surflon SC-102, Surflon SC-103, Surflon SC-104, Surflon SC-105, and Surflon SC-106 (manufactured by AGC Seimi Chemical Co., Ltd.), and/or the like.

The surfactant may be included in an amount in a range of about 0 parts by weight to about 20 parts by weight based on 100 parts by weight of the base resin. One type of the surfactant may be used, or a combination of two or more different types of the surfactant may be used.

A method of mixing the photoreactive polymer compound, the base resin, the photoacid generator, and optional components added as necessary in the organic solvent may be used. The temperature or time at the time of mixing is not particularly limited. In at least some embodiments, filtration may be performed after the mixing as necessary.

### [Pattern Formation Method]

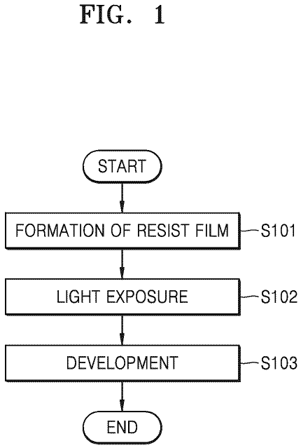

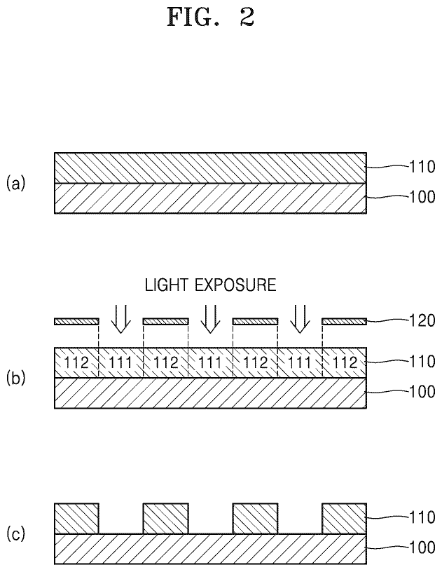

Hereinafter, a method of forming a pattern according to an embodiment will be described in detail with reference to FIGS. 1 and 2. FIG. 1 is a flowchart representing a pattern forming method according to at least one embodiment, and FIG. 2 is a side cross-sectional view illustrating a pattern forming method according to an embodiment. Hereinafter, a method of forming a pattern by using a positive photoresist composition will be described in detail as an example, but the embodiments are not limited thereto.

Referring to FIG. 1, a method of forming a pattern includes: forming a photoresist film by applying a photoresist composition (S101); exposing at least a portion of the photoresist film with high-energy rays (S102); and developing the exposed photoresist film by using a developing solution (S103). The steps above may be repeated and/or omitted as necessary, or may be performed in different orders.

Referring to FIG. 2, a substrate 100 is prepared. The substrate 100 may be, for example, a semiconductor substrate (such as a silicon substrate or a germanium substrate), and/or may be formed of glass, quartz, ceramic, copper, and the like. In an embodiment, the substrate 100 may include a Group III-V compound, such as GaP, GaAs, GaSb, and/or the like.

A photoresist film 110 may be formed by coating the substrate 100 with a photoresist composition to a desired thickness according to a coating method. As needed, a heating process may be performed thereon to remove an organic solvent remaining in a photoresist film 110. The coating method may include spin coating, dipping, roller coating, or other common coating methods. Among these methods, spin coating may be particularly used, and the photoresist film 110 having a desired thickness may be formed by adjusting the viscosity, concentration, and/or spin speed of the photoresist composition. In an embodiment, a thickness of the photoresist film 110 may be in a range of about 10 nm to about 300 nm. In one or more embodiments, a thickness of the photoresist film 110 may be in a range of about 30 nm to about 200 nm.

The lower limit of a PB temperature may be 60° C. or higher, for example, 80° C. or higher. In addition, the upper limit of a PB temperature may be 150° C. or lower, for example, 140° C. or lower. The lower limit of a PB time may be 5 seconds or more, for example, 10 seconds or more. The upper limit of a PB time may be 600 seconds or less, for example, 300 seconds or less.

Before coating the substrate 100 with the photoresist composition, a film to be etched (not shown) may be further formed on the substrate 100. The film to be etched may refer to a layer in which an image is transferred from a photoresist pattern and converted into a predetermined pattern. In an embodiment, the film to be etched may be formed to include, for example, an insulating material, such as silicon oxide, silicon nitride, or silicon oxynitride. In one or more embodiments, the film to be etched may be formed to include a conductive material, such as metal, metal nitride, metal silicide, or metal silicide nitride. In one or more embodiments, the film to be etched may be formed to include a semiconductor material, such as polysilicon.

In at least one embodiment, an antireflection layer may be further formed on the substrate 100 to exhibit efficiency of the photoresist at most. The anti-reflection film may be an organic-based anti-reflection layer or an inorganic-based anti-reflection layer.

In at least one embodiment, a protective layer may be further provided on the photoresist film 110 to reduce the influence of alkaline impurities included in the process. In addition, when performing immersion exposure, for example, a protective film against immersion may be provided on the photoresist film 110 to avoid direct contact between an immersion medium and the photoresist film 110.

Next, at least a portion of the photoresist film 110 may be exposed with high-energy rays. For example, high-energy rays passing through a mask 120 may be irradiated to at least a portion of the photoresist film 110. Accordingly, the photoresist film 110 may have an exposed area 111 and an unexposed area 112.

The exposure may be carried out by irradiating high-energy rays through a mask having a predetermined (and/or otherwise set) pattern and by using liquid, such as water or the like, as a medium in some cases. Examples of the high-energy rays may include: electromagnetic waves, such as ultraviolet rays, far-ultraviolet rays, extreme ultraviolet rays (EUV rays, wavelength of 13.5 nm), X-rays, T-rays, and/or the like; charged particle beams, such as electron beams (EBs), a rays, and/or the like; and/or the like. The irradiation of such high-energy rays may be collectively referred to as “exposure”.

For use as a light source of the exposure, various types of irradiation including irradiating laser beams in the ultraviolet region, such as KrF excimer laser (wavelength of 248 nm), ArF excimer laser (wavelength of 193 nm), and F₂ excimer laser (wavelength of 157 nm), irradiating harmonic laser beams in the far ultraviolet or vacuum ultraviolet region by a wavelength conversion method using laser beams from a solid-state laser source (e.g., YAG or semiconductor laser), irradiating electron beams or EUV rays, or the like may be used. Upon the exposure, the exposure may be performed through a mask corresponding to a desired pattern. However, when the light source of the exposure is Ebs, the exposure may be performed by direct drawing without using a mask.

The integral dose of the high-energy rays may be 2,000 mJ/cm² or less, for example, 500 mJ/cm² or less, in the case of using EUV rays as the high-energy rays. In addition, in the case of using Ebs as the high-energy rays, the integral dose of the high-energy rays may be 5,000 μC/cm² or less, for example, 1,000 μC/cm² or less.

In addition, post-exposure baking (PEB) may be performed after the exposure. The lower limit of a PEB temperature may be 50° C. or higher, for example, 80° C. or higher. The upper limit of the PEB temperature may be 180° C. or less, for example, 130° C. or less. The lower limit of a PEB time may be 5 seconds or more, for example, 10 seconds or more. The upper limit of the PEB time may be 600 seconds or less, for example, 300 seconds or less.

Next, the exposed photoresist film 110 may be developed by using a developing solution. The exposed area 111 may be washed away by the developing solution, whereas the unexposed area 112 may remain without being washed away by the developing solution.

For use as the developing solution, an alkali developing solution, a developing solution containing an organic solvent (hereinafter also referred to as “organic developing solution”), and the like may be used. As a developing method, a dipping method, a puddle method, a spray method, a dynamic administration method, and the like may be used. The developing temperature may be, for example, 5° C. or more and 60° C. or less, and the developing time may be, for example, 5 seconds or more and 300 seconds or less.

The alkali developing solution may be, for example, an alkaline aqueous solution which dissolves at least one alkaline compound, such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo[5.4.0]-7-undecene (DBU), 1,5-diazabicyclo[4.3.0]-5-nonene, and/or the like. The alkaline developing solution may further include a surfactant.

The lower limit of the amount of the alkaline compound in the alkaline developing solution may be 0.1 mass % or more, for example, 0.5 mass % or more, and for example, 1 mass % or more. In addition, the upper limit of the amount of the alkaline compound in the alkaline developing solution may be 20 mass % or less, for example, 10 mass % or less, and for example, 5 mass % or less.

After the development, a resulting photoresist pattern may be washed with ultrapure water, and subsequently, the water remaining on the substrate 100 and the pattern may be removed.

As an organic solvent contained in the organic developing solution, for example, the same organic solvent as the organic solvent described in the <Organic solvent> may be used.

The lower limit of the amount of the organic solvent in the organic developing solution may be 80 mass % or more, for example, 90 mass % or more, and for example, 95 mass % or more, and for example, 99 mass % or more.

The organic developing solution may also include a surfactant. In addition, the organic developing solution may include a trace amount of moisture. In addition, upon the development, the solvent may be substituted with a solvent of a different kind from the organic developing solution to stop the development.

The photoresist pattern resulting from the development may be further washed. For use as the washing solution, ultrapure water, rinsing liquid, and the like may be used. The liquid rinse is not particularly limited as long as it does not dissolve the photoresist pattern, and a solution containing a general organic solvent may be used. For example, the rinsing liquid may be an alcohol-based solvent or an ester-based solvent. After the washing, the rinsing liquid remaining on the substrate and the pattern may be removed. In addition, when ultrapure water is used, the water remaining on the substrate and the pattern may be removed.

In addition, the developing solution may be used either individually or in a combination of two or more types.

After the photoresist pattern is formed as described above, an etching process may be performed thereon to obtain a patterned wiring substrate. An etching method may be performed by known methods including: dry etching using plasma gas; wet etching using an alkali solution, a cupric chloride solution, a ferric chloride solution; and the like.

After forming the resist pattern, plating may be performed. Although not particularly limited, a plating method may include, for example, copper plating, solder plating, nickel plating, gold plating, and the like.

The photoresist pattern remaining after the etching may be exfoliated with an organic solvent. Although not particularly limited, examples of the organic solvent may include propylene glycol monomethyl ether acetate (PGMEA) propylene glycol monomethyl ether (PGME), ethyl lactate (EL), and the like. Although not particularly limited, examples of the exfoliation method may be an immersion method, a spray method, and the like. In addition, the wiring substrate on which the photoresist pattern is formed may be a multilayer wiring substrate, and may have through holes with a small diameter.

In at least one embodiment, after the formation of the photoresist pattern, the wiring board may be formed by a so-called lift-off process in which metal is deposited in a vacuum and then the photoresist pattern is dissolved in a solution.

The disclosure will be described in more detail with reference to Examples and Comparative Examples below, but the technical scope of the disclosure is not limited thereto.

### EXAMPLES

### Synthesis Example 1: Synthesis of Compound 1

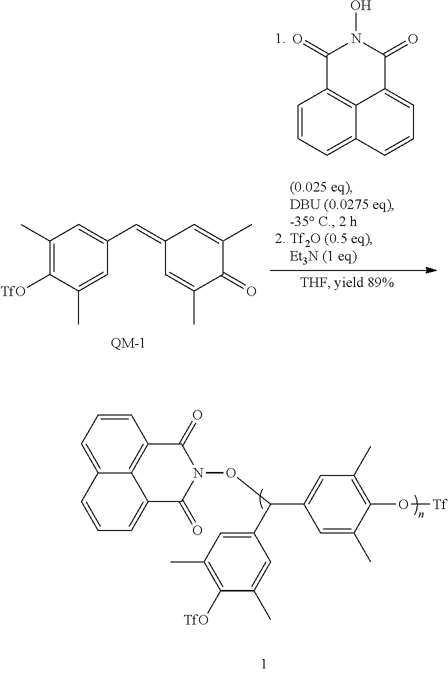

To a monomer, QM-1 (1 g, 2.59 mmol) dissolved in tetrahydrofuran (THF_(4 mL), a mixed solution containing an initiator, N-hydroxy-1,8-naphthalimide (0.065 mmol, 13.8 mg, 0.025 eq) dissolved in THF (0.1 mL), and a base, 1,8-Diazabicyclo[5.4.0]undec-7-ene (DBU_(0.071 mmol, 10.8 mg, 0.0275 eq), was added at −35° C., and the resulting mixture was stirred at the same temperature for 2 hours.

This mixture was then quenched by sequentially adding triethylamine (Et₃N_(0.26 g, 2.59 mmol, 1 eq) and triflic anhydride (Tf₂O) (0.365 g, 1.295 mmol, 0.5 eq) at a temperature in a range of −35° C. to −25° C.

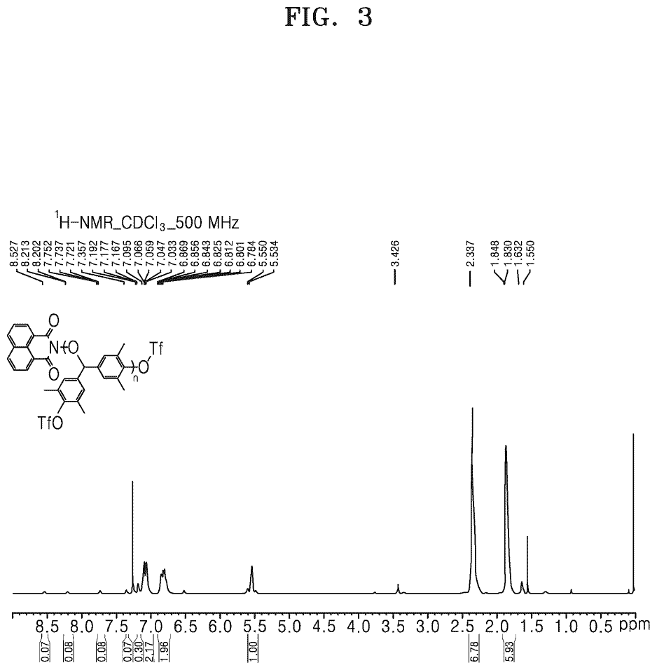

Following work-up and drying processes, a light gray solid, Compound 1, was obtained (0.89 g, yield of up to 89%). The compound thus obtained was identified by 1H nuclear magnetic resonance (NMR) and gel permeation chromatography (GPC), and the 1H NMR analysis results are shown in FIG. 3.

Mₙ=6.67 kDa, M_{w}=7.74 kDa, PDI=1.16. T_{5%} wt. loss=205° C.

### Synthesis Example 2: Synthesis of Compound 2

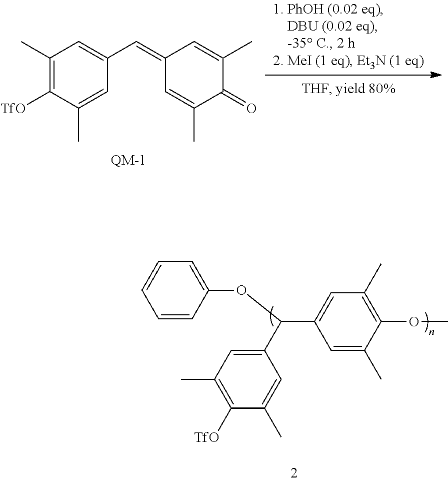

To a monomer, QM-1 (1 g, 2.59 mmol) dissolved in THF (4 mL), a mixed solution containing an initiator, phenol (PhOH) (0.052 mmol, 4.9 mg, 0.02 eq) dissolved THF (0.1 mL) and a base, DBU (0.052 mmol, 7.9 mg, 0.02 eq), was added at −35° C., and the resulting mixture was stirred at the same temperature for 2 hours.

This mixture was then quenched by sequentially adding iodomethane (Mel) (0.368 g, 2.59 mmol, 1 eq) and Et₃N (0.262 g, 2.59 mmol, 1 eq) at a temperature in a range of −35° C. to −25° C.

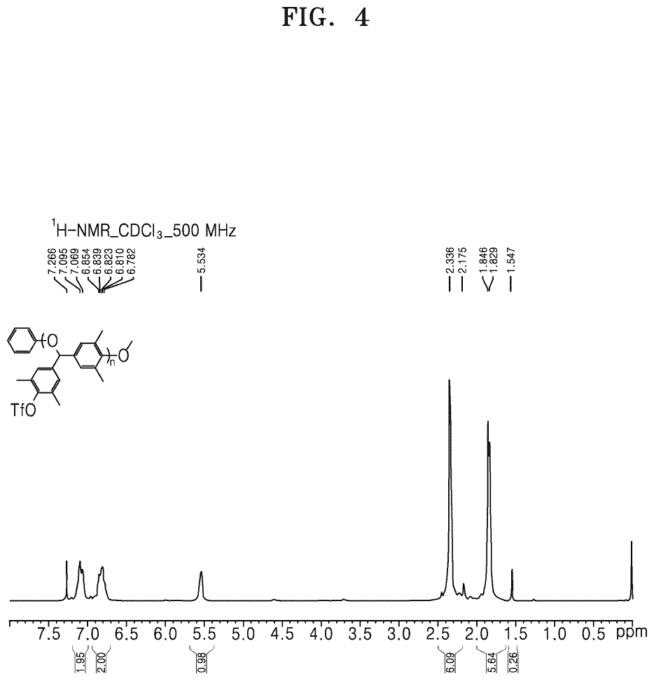

Following work-up and drying processes, a light gray solid, Compound 2, was obtained (0.80 g, yield of up to 80%). The compound thus obtained was identified by 1H NMR and GPC, and the 1H NMR analysis results are shown in FIG. 4.

Mₙ=6.75 kDa, M_{w}=8.20 kDa, PDI=1.21. T_{5%} wt. loss=223° C.

### Synthesis Example 3: Synthesis of Compound 3

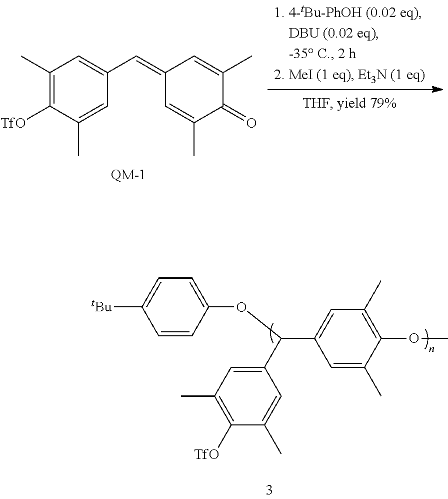

To a monomer, QM-1 (1 g, 2.59 mmol) dissolved in THF (4 mL), a mixed solution containing an initiator, 4-^{t}Bu-PhOH (0.052 mmol, 7.8 mg, 0.02 eq) dissolved THF (0.1 mL) and a base, DBU (0.052 mmol, 7.9 mg, 0.02 eq), was added at −35° C., and the resulting mixture was stirred at the same temperature for 2 hours.

This mixture was then quenched by sequentially adding Mel (0.368 g, 2.59 mmol, 1 eq) and Et₃N (0.262 g, 2.59 mmol, 1 eq) at a temperature in a range of −35° C. to −25° C.

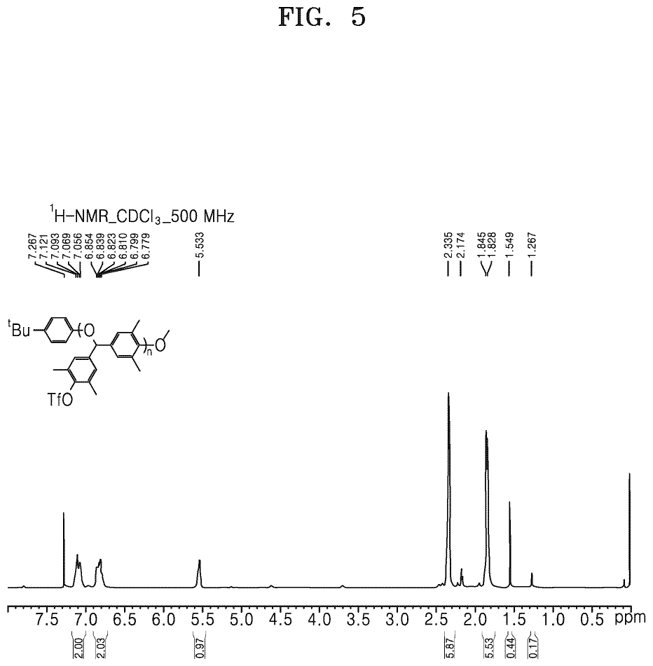

Following work-up and drying processes, a light gray solid, Compound 3, was obtained (0.79 g, yield of up to 79%). The compound thus obtained was identified by 1H NMR and GPC, and the 1H NMR analysis results are shown in FIG. 5.

Mₙ=6.59 kDa, M_{w}=8.00 kDa, PDI=1.21. T_{5%} wt. loss=219° C.

### Synthesis Example 4: Synthesis of Compound 4

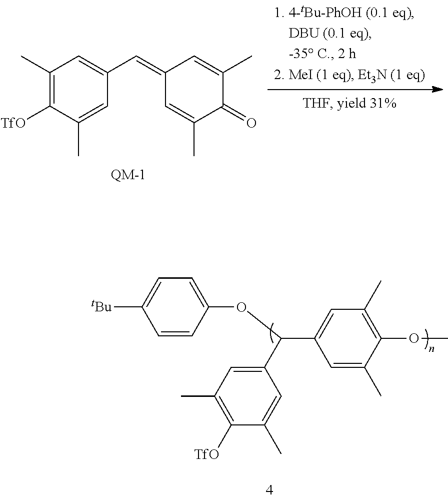

To a monomer, QM-1 (1 g, 2.59 mmol) dissolved in THF (4 mL), a mixed solution containing an initiator, 4-^{t}Bu-PhOH (0.259 mmol, 38.9 mg, 0.1 eq) dissolved THF (0.1 mL) and a base, DBU (0.259 mmol, 39.4 mg, 0.1 eq), was added at −35° C., and the resulting mixture was stirred at the same temperature for 2 hours.

This mixture was then quenched by sequentially adding Mel (0.368 g, 2.59 mmol, 1 eq) and Et₃N (0.262 g, 2.59 mmol, 1 eq) at a temperature in a range of −35° C. to −25° C.

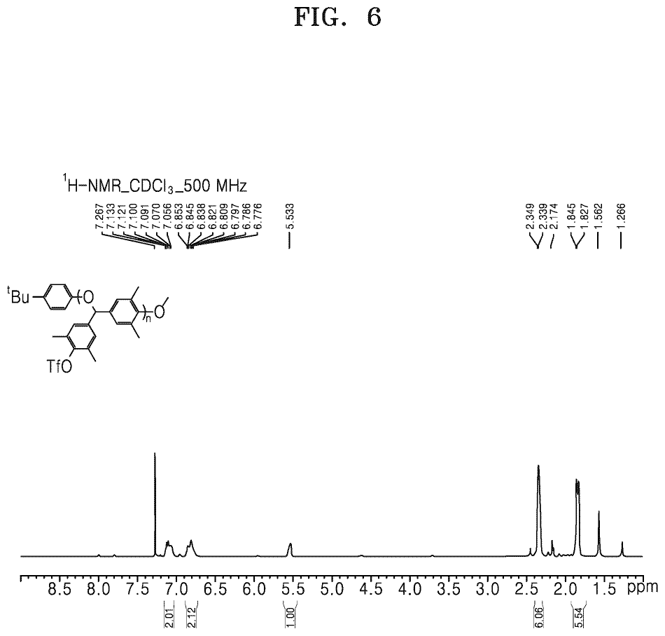

Following work-up and drying processes, a light gray solid, Compound 4, was obtained (0.31 g, yield of up to 31%). The compound thus obtained was identified by 1H NMR and GPC, and the 1H NMR analysis results are shown in FIG. 6.

Mₙ=3.99 kDa, M_{w}=4.89 kDa, PDI=1.23. T_{5%} wt. loss=214° C.

### Synthesis Example 5: Synthesis of Compound 5

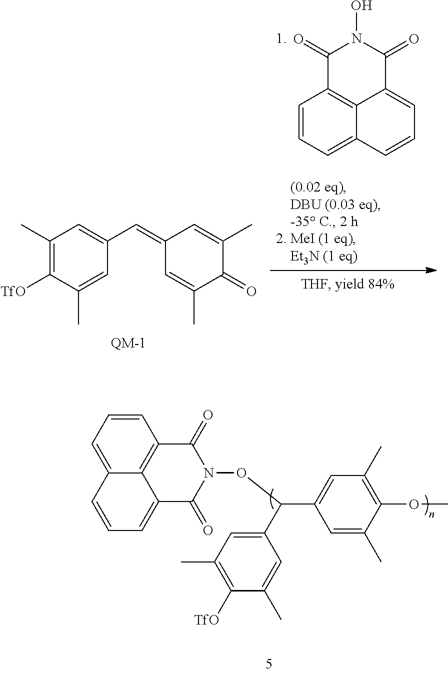

To a monomer, QM-1 (1 g, 2.59 mmol) dissolved in THF (4 mL), a mixed solution containing an initiator, N-hydroxy-1,8-naphthalimide (0.052 mmol, 11 mg, 0.02 eq) dissolved THF (0.1 mL) and a base, DBU (0.077 mmol, 11.8 mg, 0.03 eq), was added at −35° C., and the resulting mixture was stirred at the same temperature for 2 hours.

This mixture was then quenched by sequentially adding Mel (0.368 g, 2.59 mmol, 1 eq) and Et₃N (0.262 g, 2.59 mmol, 1 eq) at a temperature in a range of −35° C. to −25° C.

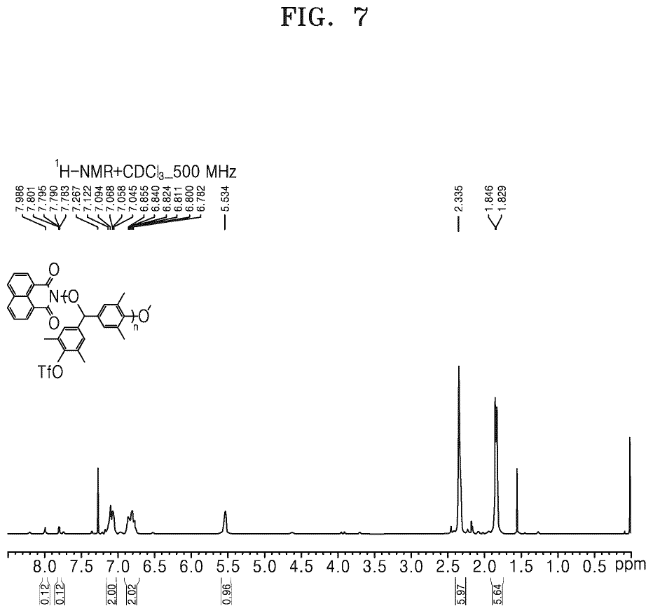

Following work-up and drying processes, a light gray solid, Compound 5, was obtained (0.84 g, yield of up to 84%). The compound thus obtained was identified by 1H NMR and GPC, and the 1H NMR analysis results are shown in FIG. 7.

Mₙ=6.52 kDa, M_{w}=7.55 kDa, PDI=1.16. T_{5%} wt. loss=211° C.

### Synthesis Example 6: Synthesis of Compound 6

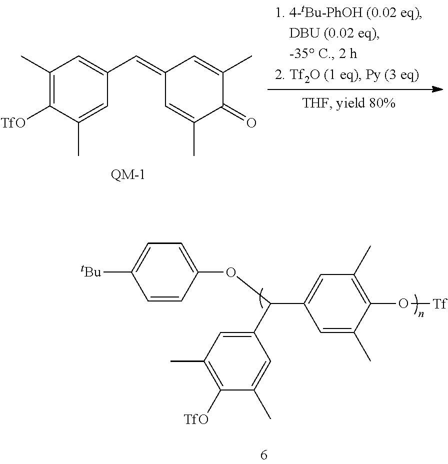

To a monomer, QM-1 (1 g, 2.59 mmol) dissolved in THF (4 mL), a mixed solution containing an initiator, 4-^{t}Bu-PhOH (0.052 mmol, 7.8 mg, 0.02 eq) dissolved THF (0.2 mL) and a base, DBU (0.077 mmol, 11.8 mg, 0.03 eq), was added at −35° C., and the resulting mixture was stirred at the same temperature for 2 hours.

This mixture was then quenched by sequentially adding pyridine (0.615 gr, 7.77 mmol, 3 eq) and Tf₂O (0.73 gr, 2.59 mmol, 1 eq) at a temperature in a range of −35° C. to −25° C.

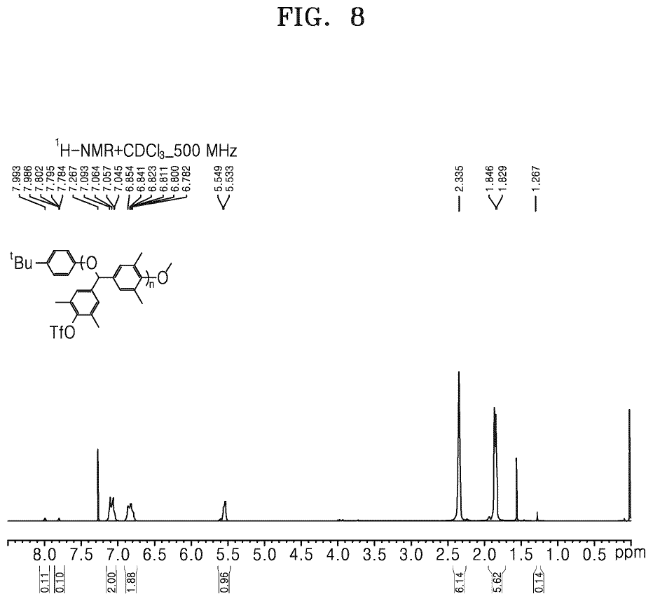

Following work-up and drying processes, a light gray solid, Compound 6, was obtained (0.80 g, yield of up to 80%). The compound thus obtained was identified by 1H NMR and GPC, and the 1H NMR analysis results are shown in FIG. 8.

Mₙ=7.20 kDa, M_{w}=8.54 kDa, PDI=1.19. T_{5%} wt. loss=219° C.

### Evaluation Example 1: Evaluation of Thermal Stability

For each compound listed in Table 1 below, about 5 mg to about 10 mg of each compound was used for thermal analysis by discovery thermo gravimetric analysis (TGA) (N₂ atmosphere, temperature interval: at room temperature to 600° C. (10° C./min)-TGA, Pan Type: Pt Pan in disposable A1 Pan(TGA)), and the 5% mass reduction temperature (T_{d5%}) for each compound was summarized in Table 1. During the TGA, the temperature at which the mass of each sample reached 95% of the initial mass of the same was expressed as T_{d5%}.

### Evaluation Example 2: Evaluation of Pattern Formation

Each compound listed in Table 1 was dissolved in a mixture of propylene glycol methyl ether (PGME) and propylene glycol methyl ether acetate (PGMEA) to prepare a 1 wt % to 4 wt % resist solution. Before applying the resist, a substrate was treated with hexamethyldisilaazane (HMDS), a single layer of a photoresist primer, to ensure excellent photoresist adhesion.

The resist solution was filtered through a 0.2 m membrane filter, applied onto a silicon wafer by spin coating to form a thin film having a thickness of 40 nm to 50 nm, and then applied at 90° C. for 60 seconds by using a hot plate to remove an excessive casting solvent. Afterwards, post-apply baking (PAB) was performed on the resist film. Next, the resist film was exposed to EUV radiation. Here, the post exposure baking (PEB) conditions were set at 80° C. to 120° C. for 60 seconds. The resist film was developed with 2.38 wt % TMAH, and then washed with deionized water to remove the coated portion not exposed to EUV radiation, followed by drying, so as to form a resist pattern.

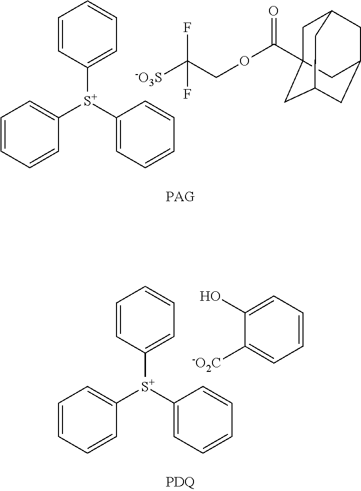

In Table 1, Etₕ refers to the exposure amount at the point where the thin film begins to develop, and E₀ refers to the exposure amount at the point where the thin film is completely developed (i.e., at the point where the thickness of the thin film no longer decreases). γ refers to a contrast curve as a value calculated by Equation 1 below:

$$γ = {[ ln \frac{E 0}{Eth} ]}^{- 1} \qquad Equation 1$$

TABLE 1

| | Molecular | | | EUV dose | | |
|---|---|---|---|---|---|---|
| | weight | | T_{d5%} | (mJ/cm²) | | contrast, |
| Compound | (M_{w}, g/mol) | PDI | (° C.) | Eₜₕ | E₀ | γ |
| Compound 1 | 7736 | 1.16 | 205 | 4.74 | 9.24 | 1.5 |
| Compound 2 | 8204 | 1.21 | 222 | 27.29 | 34.86 | 4.22 |
| Compound 3 | 8000 | 1.21 | 219 | 18.15 | 23.07 | 4.27 |
| Compound 4 | 4887 | 1.23 | 214 | 44.31 | 83.52 | 1.67 |
| Compound 5 | 7554 | 1.16 | 211 | 24.51 | 29.62 | 5.25 |
| Compound 6 | 8539 | 1.19 | 219 | 13.66 | 19.24 | 3.05 |

Referring to Table 1, it was confirmed that the photoreactive polymer compound according to the example embodiments may have excellent photosensitivity.

According to the one or more embodiments, a photoreactive polymer compound may have excellent sensitivity to light exposure, a low polydiversity index (PDI), and excellent thermal stability. In this regard, the photoresist composition according to an embodiment may have excellent properties such as improved developability and/or improved resolution, etc.

It should be understood that the embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A photoreactive polymer compound comprising a first repeating unit represented by Formula 1: 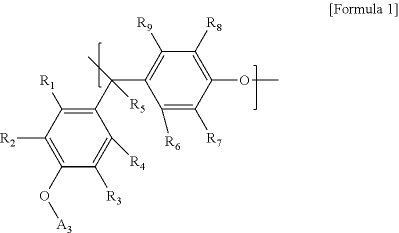
wherein, in Formula 1,
A₃ and R₁ to R₉ are each independently: hydrogen; deuterium; a halogen; a cyano group; a nitro group; a hydroxy group; a C₁-C₃₀ monovalent hydrocarbon group that optionally includes a heteroatom; or —N(Q₁)(Q₂),
Q₁ and Q₂ are each independently: hydrogen; deuterium; or a linear, branched, or cyclic C₁-C₂₀ monovalent hydrocarbon group that optionally includes a heteroatom, and
the photoreactive polymer compound comprises at least one photosensitive group.

2. The photoreactive polymer compound of claim 1, wherein the photosensitive group is reactive to at least one of visible light, ultraviolet (UV) rays, deep ultraviolet (DUV) rays, extreme ultraviolet (EUV) rays, electron beams (EBs), or X-rays.

3. The photoreactive polymer compound of claim 1, wherein the photoreactive polymer compound is configured to undergo continuous depolymerization when exposed to light.

4. The photoreactive polymer compound of claim 1, further comprising a second repeating unit represented by Formula 2: 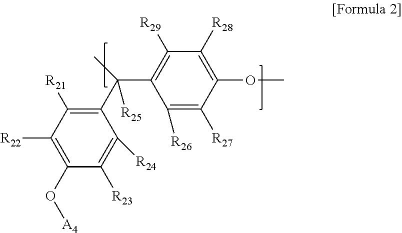
wherein, in Formula 2,
A₄ and R₂₁ to R₂₉ are each independently: hydrogen; deuterium; a halogen; a cyano group; a hydroxy group; a C₁-C₃₀ monovalent hydrocarbon group that optionally includes a heteroatom; or —N(Q₃)(Q₄),
Q₃ and Q₄ are each independently: hydrogen; deuterium; or a C₁-C₃₀ monovalent hydrocarbon group that optionally includes a heteroatom, and
the first repeating unit is different from the second repeating unit.

5. The photoreactive polymer compound of claim 4, wherein the photoreactive polymer compound includes at least one of a random copolymer, a block copolymer, an alternating copolymer, a graft copolymer, or a combination thereof including the first repeating unit and the second repeating unit.

6. The photoreactive polymer compound of claim 1, wherein the photoreactive polymer compound is represented by at least one of Formula 11 or 21: 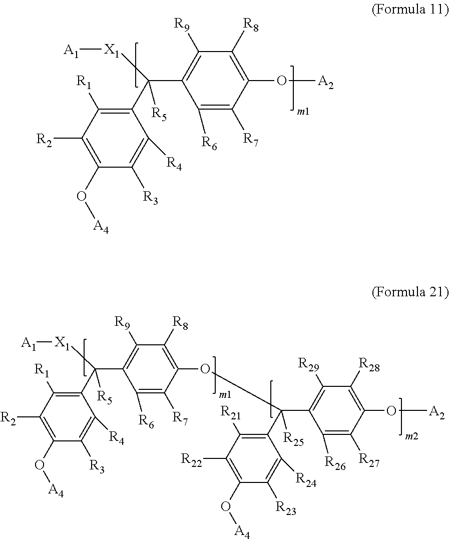
wherein, in Formulae 11 and 21,
X₁ is O, S, Se, N(R₁₀), C(R₁₁)(R₁₂), or Si(R₁₃)(R₁₄),
A₁ to A₃ and R₁ to R₁₄ are each independently: hydrogen; deuterium; a halogen; a cyano group; a hydroxy group; a linear, branched, or cyclic C₁-C₂₀ monovalent hydrocarbon group that optionally includes a heteroatom; or —N(Q₁)(Q₂),
A₄ and R₂₁ to R₂₉ are each independently: hydrogen; deuterium; a halogen; a cyano group; a hydroxy group; a linear, branched, or cyclic C₁-C₂₀ monovalent hydrocarbon group that optionally includes a heteroatom; or —N(Q₃)(Q₄),
Q₁ to Q₄ are each independently: hydrogen; deuterium; or a linear, branched, or cyclic C₁-C₂₀ monovalent hydrocarbon group that optionally includes a heteroatom, and
m1 and m2 are each independently an integer included in a range from 2 to 10,000.

7. The photoreactive polymer compound of claim 6, wherein at least one of A₁ to A₃ is a C₁-C₂₀ alkyl group or represented by one of Formulae 3-1 to 3-27: 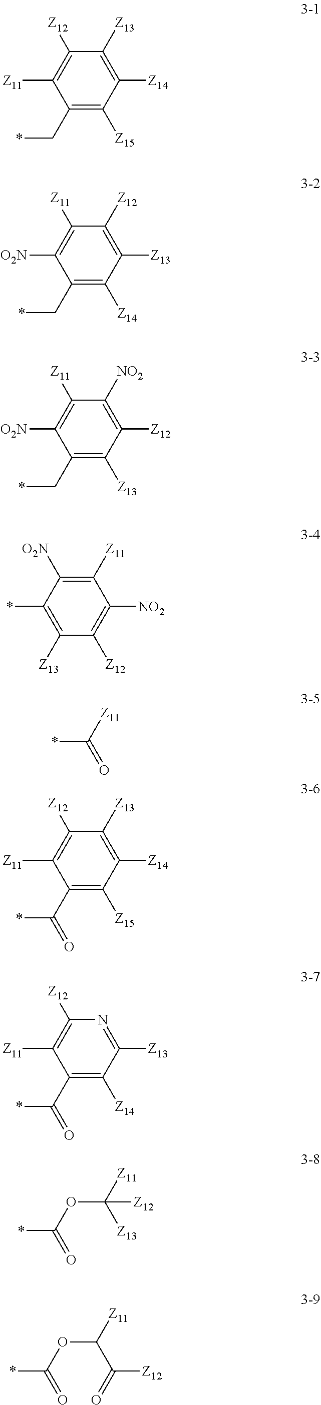 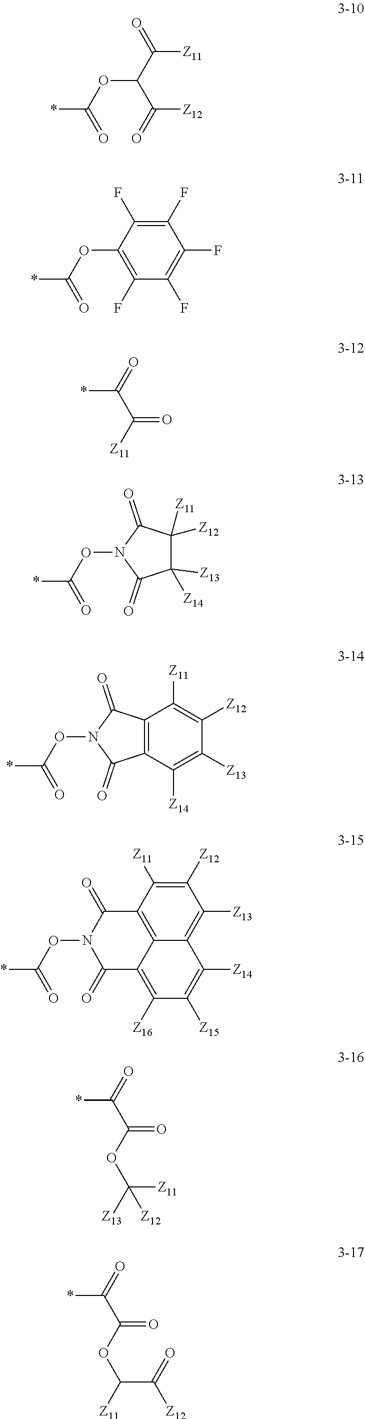 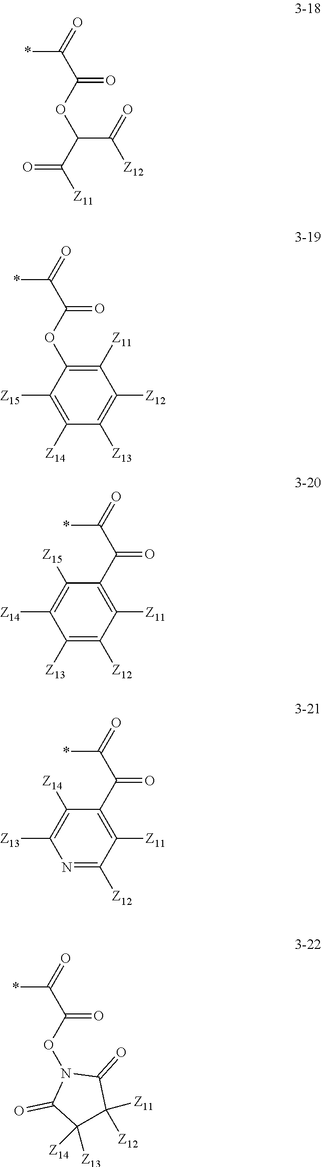 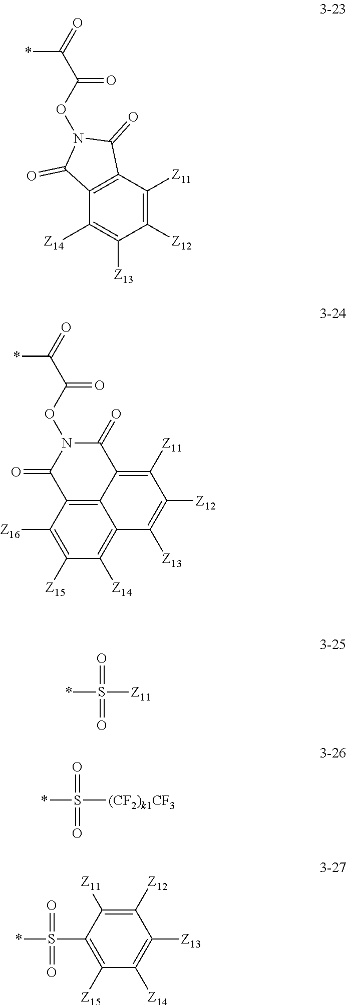
wherein, in Formulae 3-1 to 3-27,
Z₁₁ to Z₁₆ are each independently: one of hydrogen, deuterium, a halogen, a hydroxyl group, a C₁-C₂₀ alkyl group, a C₁-C₂₀ fluoroalkyl group, a C₁-C₂₀ alkoxy group, a C₃-C₂₀ cycloalkyl group, a C₁-C₂₀ heterocycloalkyl group, a C₆-C₂₀ aryl group, a C₆-C₂₀ aryloxy group, a C₃-C₂₀ heteroaryl group, or a C₃-C₂₀ heteroaryloxy group; or
one of a C₁-C₂₀ alkyl group, a C₁-C₂₀ fluoroalkyl group, a C₁-C₂₀ alkoxy group, a C₃-C₂₀ cycloalkyl group, a C₁-C₂₀ heterocycloalkyl group, a C₆-C₂₀ aryl group, a C₆-C₂₀ aryloxy group, a C₃-C₂₀ heteroaryl group, or a C₃-C₂₀ heteroaryloxy group, each substituted with deuterium, a halogen, a hydroxyl group, a C₁-C₂₀ alkyl group, a C₁-C₂₀ fluoroalkyl group, a C₁-C₂₀ alkoxy group, a C₃-C₂₀ cycloalkyl group, a C₁-C₂₀ heterocycloalkyl group, a C₆-C₂₀ aryl group, a C₆-C₂₀ aryloxy group, a C₃-C₂₀ heteroaryl group, a C₃-C₂₀ heteroaryloxy group, or a combination thereof,
k1 is an integer included in a range from 1 to 20, and
* indicates a binding site to a neighboring atom.

8. The photoreactive polymer compound of claim 7, wherein A₃ is represented by one of the Formulae 3-1 to 3-27.

9. The photoreactive polymer compound of claim 6, wherein the A₁-X₁—* moiety is represented by one of Formulae 5-1 to 5-31: 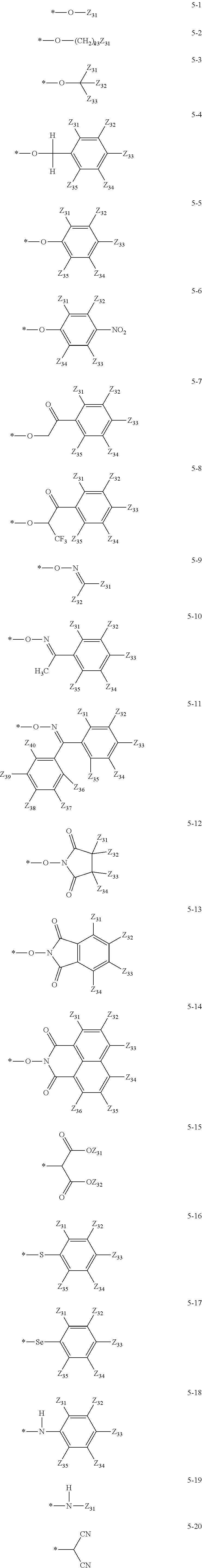 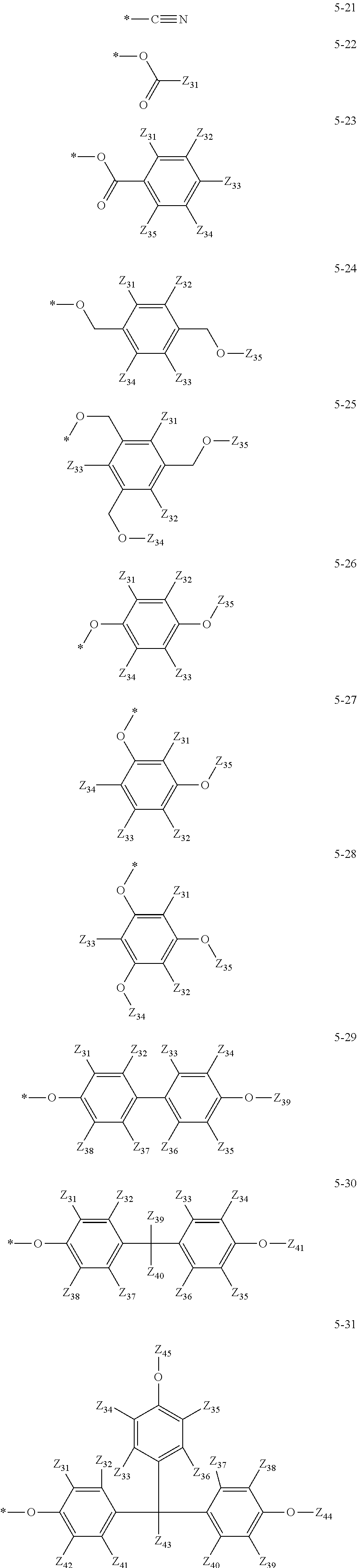
wherein, in Formulae 5-1 to 5-31,
Z₃₁ to Z₄₅ are each independently: one of hydrogen, deuterium, a halogen, a hydroxyl group, a C₁-C₂₀ alkyl group, a C₁-C₂₀ fluoroalkyl group, a C₁-C₂₀ alkoxy group, a C₃-C₂₀ cycloalkyl group, a C₁-C₂₀ heterocycloalkyl group, a C₆-C₂₀ aryl group, a C₆-C₂₀ aryloxy group, a C₃-C₂₀ heteroaryl group, or a C₃-C₂₀ heteroaryloxy group; or
one of a C₁-C₂₀ alkyl group, a C₁-C₂₀ fluoroalkyl group, a C₁-C₂₀ alkoxy group, a C₃-C₂₀ cycloalkyl group, a C₁-C₂₀ heterocycloalkyl group, a C₆-C₂₀ aryl group, a C₆-C₂₀ aryloxy group, a C₃-C₂₀ heteroaryl group, or a C₃-C₂₀ heteroaryloxy group, each substituted with deuterium, a halogen, a hydroxyl group, a C₁-C₂₀ alkyl group, a C₁-C₂₀ fluoroalkyl group, a C₁-C₂₀ alkoxy group, a C₃-C₂₀ cycloalkyl group, a C₁-C₂₀ heterocycloalkyl group, a C₆-C₂₀ aryl group, a C₆-C₂₀ aryloxy group, a C₃-C₂₀ heteroaryl group, a C₃-C₂₀ heteroaryloxy group, or a combination thereof,
k3 is an integer included in a range from 1 to 20, and
* indicates a binding site to a neighboring atom.

10. The photoreactive polymer compound of claim 1, wherein R₁ to R₁₄ and R₂₁ to R₂₉ are each independently:
one of hydrogen, deuterium, a halogen, a hydroxyl group, a C₁-C₂₀ alkyl group, a C₁-C₂₀ fluoroalkyl group, a C₁-C₂₀ alkoxy group, a C₃-C₂₀ cycloalkyl group, a C₁-C₂₀ heterocycloalkyl group, a C₆-C₂₀ aryl group, a C₆-C₂₀ aryloxy group, a C₃-C₂₀ heteroaryl group, or a C₃-C₂₀ heteroaryloxy group; or
one of a C₁-C₂₀ alkyl group, a C₁-C₂₀ fluoroalkyl group, a C₁-C₂₀ alkoxy group, a C₃-C₂₀ cycloalkyl group, a C₁-C₂₀ heterocycloalkyl group, a C₆-C₂₀ aryl group, a C₆-C₂₀ aryloxy group, a C₃-C₂₀ heteroaryl group, or a C₃-C₂₀ heteroaryloxy group, each substituted with deuterium, a halogen, a hydroxyl group, a C₁-C₂₀ alkyl group, a C₁-C₂₀ fluoroalkyl group, a C₁-C₂₀ alkoxy group, a C₃-C₂₀ cycloalkyl group, a C₁-C₂₀ heterocycloalkyl group, a C₆-C₂₀ aryl group, a C₆-C₂₀ aryloxy group, a C₃-C₂₀ heteroaryl group, a C₃-C₂₀ heteroaryloxy group, or a combination thereof.

11. The photoreactive polymer compound of claim 1, wherein the photoreactive polymer compound has a weight average molecular weight in a range of 3,000 g/mol to 30,000 g/mol.

12. The photoreactive polymer compound of claim 1, wherein the photoreactive polymer compound has a polydiversity index (PDI) in a range of 1 to 1.5.

13. The photoreactive polymer compound of claim 1, wherein the photoreactive polymer compound is represented by one of Formulae P1 to P5: 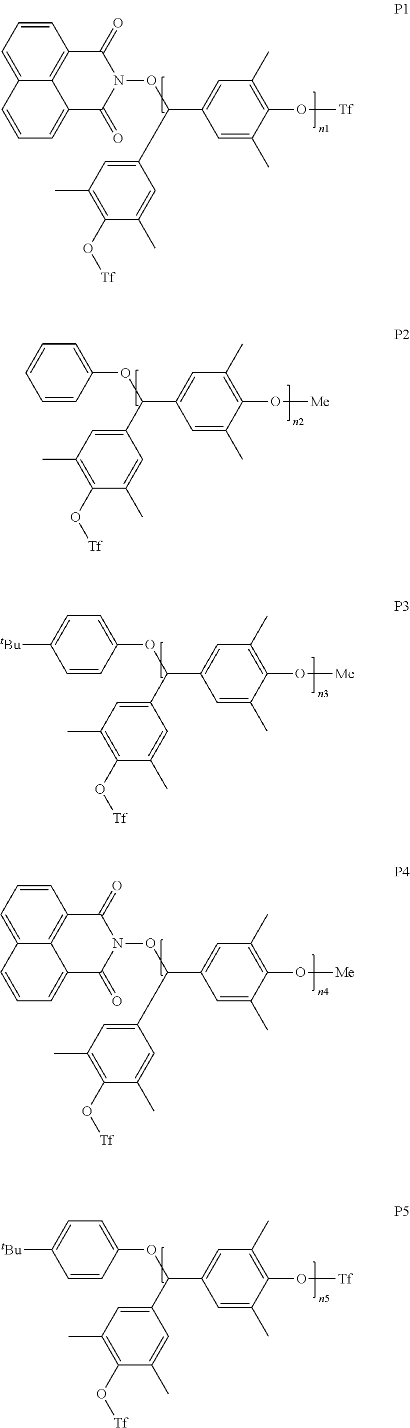
wherein, in Formulae P1 to P5,
Tf is a triflate group,
Me is a methyl group,
^{t}Bu is a tert-butyl group, and
n1 to n5 are each independently an integer in a range of 2 to 10,000.

14. A photoresist composition comprising the photoreactive polymer compound of claim 1.

15. The photoresist composition of claim 14, further comprising:
at least one of a photoacid generator, an organic solvent, a base resin, or a photodegradable quencher.

16. The photoresist composition of claim 14, wherein the photoresist composition does not comprise a photoacid generator.

17. The photoresist composition of claim 15, wherein the photoresist composition is a positive tone photoresist composition.

18. The photoresist composition of claim 15, wherein the photoresist composition is a non-chemically amplified (non-CA) type.

19. A method of forming a pattern, the method comprising:
forming a photoresist film by coating a substrate with the photoresist composition of claim 15;
exposing at least a portion of the photoresist film to high-energy rays; and
developing the exposed photoresist film using a developing solution.

20. The method of claim 19, wherein the exposing includes irradiating the photoresist film with at least one of ultraviolet (UV) rays, deep ultraviolet (DUV) rays, extreme ultraviolet (EUV) rays, or electron beams (EBs).
